(19) United States
(12) Patent Application Publication
(10) Pub. No.: US 2016/0005749 A1
(43) Pub. Date: Jan. 7, 2016

(54) SERIES FERROELECTRIC NEGATIVE CAPACITOR FOR MULTIPLE TIME PROGRAMMABLE (MTP) DEVICES

(71) Applicant: QUALCOMM Incorporated, San Diego, CA (US)

(72) Inventors: Xia LI, San Diego, CA (US); Bin YANG, San Diego, CA (US); Daniel Wayne PERRY, San Diego, CA (US)

(21) Appl. No.: 14/321,593

(22) Filed: Jul. 1, 2014

(51) Int. Cl. H01L 27/115; H01L 49/02; H01L 21/28

(52) U.S. Cl. CPC H01L 27/11521; H01L 27/11507; H01L 21/28273; H01L 28/56

(57) ABSTRACT

Implementations of the technology described herein provide a Multiple Time Programmable (MTP) device, such as a Flash memory device, that implements a coupling gate in series with a floating gate. The coupling gate includes a ferroelectric capacitor and a conventional capacitor. The ferroelectric capacitor in combination with the coupling gate provides a negative capacitance such that the total capacitance of the combination of the floating gate and the coupling gate is larger than it would be if the coupling gate included only a conventional capacitor. One advantage of this device is that the effective coupling ratio between the coupling gate and the floating gate is increased. Another advantage is that the floating gate drops more voltage than conventional Multiple Time Programmable (MTP) devices.

### FIELD OF DISCLOSURE

The technology described herein is directed to memory devices, and in particular, to Multiple Time Programmable (MTP) memory devices.

### BACKGROUND

Market demand has been growing for nonvolatile memory devices in which data can be electrically written and rewritten, and in which data can be stored even after power is removed. These devices can be referred to as Multiple Time Programmable (MTP) devices. One such Multiple Time Programmable (MTP) device includes a silicon substrate, a tunneling oxide on the silicon substrate, a polysilicon floating gate on the tunneling oxide, an inter-plate dielectric (IPD) on the floating gate, and a control gate on the inter-plate dielectric (IPD). The control gate is arranged in series with the floating gate.

To program the Multiple Time Programmable (MTP) device, a voltage is applied to the control gate. This causes electrons or holes to be injected through the floating gate. To erase the Multiple Time Programmable (MTP) device electrons or holes are removed from the floating gate. Charge should move to the floating gate from the silicon substrate but not move from the floating gate to the control gate. One function of the inter-plate dielectric (IPD) is to prevent charge from moving from the floating gate to the control gate.

In many circumstances, the capacitance of the control gate should be larger than the capacitance of the floating gate so that the coupling ratio between the control gate and the floating gate is good. The coupling ratio is a measure of how strongly the control gate is coupled to the floating-gate.

The coupling ratio may determine the electric fields across the tunneling oxide of the floating gate and the control oxide of the control gate. The field across the tunnel oxide controls the speed of operation of the device. A device with a lower coupling ratio may operate at lower tunnel oxide fields compared to a device with higher coupling ratio at the same voltages. It follows that a device with lower coupling ratio may need higher voltages to operate at the same speed (the same tunnel oxide field). This also means that the field in the inter-plate dielectric (IPD) may be larger, which is undesirable.

A larger control gate capacitance is conventionally achieved by using a larger control gate. Conventionally, however, a larger control gate means that more area on the Multiple Time Programmable (MTP) device is consumed by the control gate.

Moreover, in general, the thickness of the control gate is greater than the thickness of the floating gate. This contributes to the capacitance of the control gate being less than the capacitance of the floating gate, and the two capacitances arranged in series results in the floating gate undesirably dropping less voltage than the control gate.

Additionally, because the control gate is arranged in series with the floating gate, and because the control gate capacitor is smaller than the floating gate, the coupling ratio between the control gate and the floating gate is rather small.

As such, techniques are needed to improve the coupling ratio of the control gate and the floating gate.

### SUMMARY

Example implementations of the technology described herein are directed to a mechanism for using a ferroelectric negative capacitor in series with a conventional coupling gate capacitor to enlarge the coupling gate capacitor and the coupling ratio for a floating gate Multiple Time Programmable (MTP) device, a FinFET device, and/or the like. In one or more implementations, the mechanism includes systems, methods, apparatuses, and (non-transitory) computer readable media that implement the technology described herein.

For example, in one or more implementations, a multiple time programmable memory includes a negative capacitor (or capacitance) and a first transistor having a floating gate. The floating gate is coupled in series with the negative capacitor. The negative capacitor includes a ferroelectric capacitor (or capacitance) and an inter-plate dielectric capacitor (or capacitance). The first transistor is at least one of an NMOS transistor and a PMOS transistor. The multiple time programmable device further includes a control gate coupled in series with the negative capacitor.

In one or more implementations, a method for making a multiple time programmable memory includes forming a negative capacitor on a substrate and forming a first transistor on the substrate. The first transistor includes a floating gate. The method also includes coupling the floating gate in series with the negative capacitor. The negative capacitor includes ferroelectric material and an inter-plate dielectric material. Forming the negative capacitor on the substrate includes forming a gate oxide material on the substrate, forming the floating gate material on the gate oxide material, forming the inter-plate dielectric material on the floating gate material, and forming the ferroelectric material on the inter-plate dielectric material.

An alternative method for making a multiple time programmable memory includes a step for forming a negative capacitor on a substrate and a step for forming a first transistor on the substrate. The first transistor includes a floating gate. The method further includes a step for coupling the floating gate in series with the negative capacitor.

An alternative multiple time programmable memory includes a negative capacitance means and a first transistor having a floating gate, wherein the floating gate is coupled in series with the negative capacitance means. The negative capacitor means includes a ferroelectric capacitor means and an inter-plate dielectric capacitance means. A control gate coupled in series with the negative capacitance means.

Above is a simplified Summary relating to one or more implementations described herein. As such, the Summary should not be considered an extensive overview relating to all contemplated aspects and/or implementations, nor should the Summary be regarded to identify key or critical elements relating to all contemplated aspects and/or implementations or to delineate the scope associated with any particular aspect and/or implementation. Accordingly, the Summary has the sole purpose of presenting certain concepts relating to one or more aspects and/or implementations relating to the mechanisms disclosed herein in a simplified form to precede the detailed description presented below.

### BRIEF DESCRIPTION OF THE DRAWINGS

FIG. 1 is a schematic diagram of a two-transistor (2T) p-channel metal-oxide-semiconductor (PMOS) cell of a Multiple Time Programmable (MTP) device according to an example implementation of the technology described herein.

FIG. 2 is a schematic diagram of a three-transistor (3T) p-channel metal-oxide-semiconductor (PMOS) cell of a Multiple Time Programmable (MTP) device according to an example implementation of the technology described herein.

FIG. 3 is a schematic diagram of a two-transistor (2T) n-channel metal-oxide-semiconductor (NMOS) cell of a Multiple Time Programmable (MTP) device according to an example implementation of the technology described herein.

FIG. 4 is a schematic diagram of a three-transistor (3T) n-channel metal-oxide-semiconductor (NMOS) cell of a Multiple Time Programmable (MTP) device according to an example implementation of the technology described herein.

FIGS. 5A and 5B are cross-sectional views of a Multiple Time Programmable (MTP) device according to an example implementations of the technology described herein.

FIGS. 6 through 22 are cross-sectional views of a Multiple Time Programmable (MTP) device according to an example implementations of the technology described herein.

FIGS. 23A through 23D illustrate a process integration flow for a method of making a Multiple Time Programmable (MTP) device according to an example implementations of the technology described herein.

FIG. 24 illustrates a process integration flow for a method of making a Multiple Time Programmable (MTP) device according to an example implementation of the technology described herein.

FIG. 25 illustrates graphical representations of modeling of a negative capacitor for a Multiple Time Programmable (MTP) device according to an example implementation of the technology described herein.

The Detailed Description references the accompanying figures. In the figures, the left-most digit(s) of a reference number identifies the figure in which the reference number first appears. The same numbers are used throughout the drawings to reference like features and components.

### DETAILED DESCRIPTION

In general, one implementation of the subject matter disclosed herein is directed to a Multiple Time Programmable (MTP) device, such as a Flash memory device, that implements a coupling gate in series with a floating gate. The coupling gate includes a ferroelectric capacitor and a conventional capacitor. Conventionally, capacitors in parallel with each other increase overall capacitance of the capacitor circuit whereas capacitors in series with each other decrease overall capacitance of the capacitor circuit. Unlike conventional circuits in series with each other, however, the ferroelectric capacitor in the coupling gate provides a negative capacitance such that the total capacitance of the combination of the floating gate and the coupling gate is smaller than it would be if the coupling gate included only a conventional capacitor.

One advantage of this arrangement is that the effective coupling ratio between the coupling gate and the floating gate is increased. Another advantage of this arrangement is that the floating gate can now drop more voltage than conventional Multiple Time Programmable (MTP) devices.

In one or more implementations, the coupling gate may be used for a gate last or a gate first high-k/metal gate process. In implementations in which the control gate is used in an N gate/P-channel floating gate environment, the corresponding bit cell may have a better read disturb performance. The corresponding bit cell also may have better endurance (i.e., the cycling or the number of times that the bit cell may be written may be improved). In one or more implementations, programming a bit cell according to the technology described herein uses channel hot carrier (CHE) injection. Erasing a bit cell according to the technology described herein uses Fowler-Nordheim (F-N) tunneling. Using the coupling gate having a ferroelectric capacitor according to the technology described herein may reduce bit cell program voltage and bit cell erase voltage over conventional bit cell operations.

### Example 2T PMOS MTP Cell

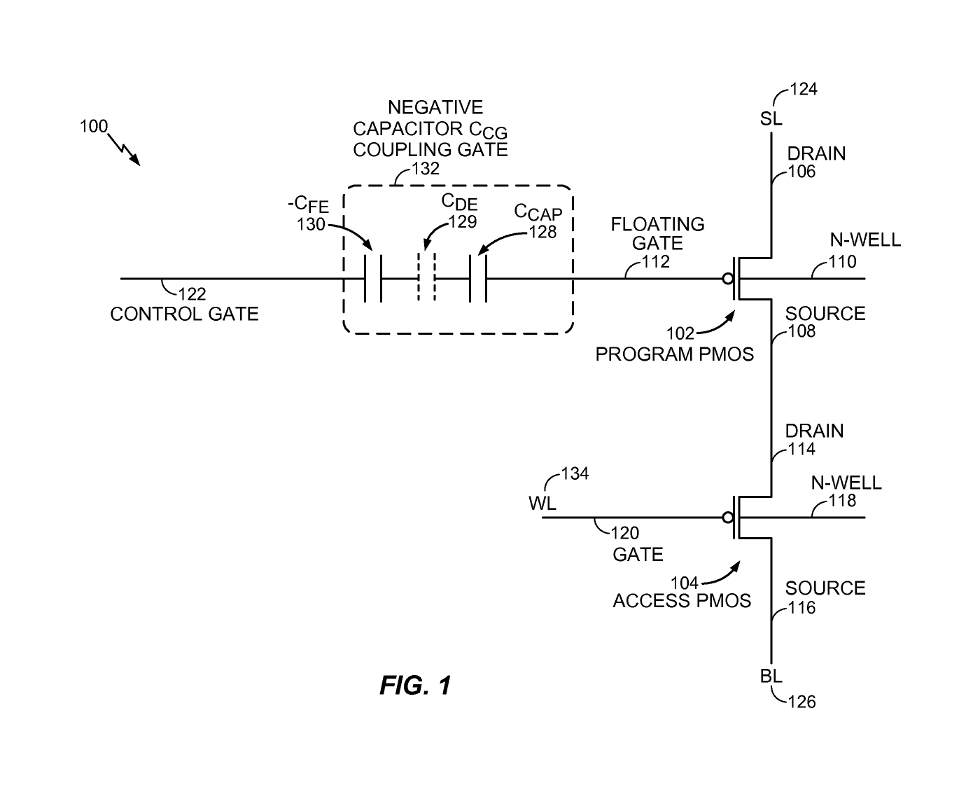

FIG. 1 is a schematic diagram of a two-transistor (2T) p-channel metal-oxide-semiconductor (PMOS) cell 100 of a Multiple Time Programmable (MTP) device according to an example implementation of the technology described herein. In one or more implementations, the cell 100 may be implemented in a ferroelectric control gate MTP device. Ferroelectric control gates may be incorporated in systems where power conservation is a consideration, such as embedded memory applications for mobile devices. In one or more implementations, the cell 100 can be an N metal gate with a P channel. Alternatively, in one or more implementations, the cell 100 can be a P metal gate with an P channel.

The illustrated cell 100 includes a program PMOS transistor 102 and an access PMOS transistor 104. The program PMOS transistor 102 includes a drain 106, a source 108, and n-well 110, and a floating gate 112. The access PMOS 104 includes a drain 114, a source 116, an n-well 118, and a gate 120. The cell 100 also includes a control gate 122, a source line (SL) 124, and a bit line (BL) 126. A coupling capacitor 128 and a ferroelectric capacitor 130 form a negative capacitor coupling gate 132. A word line (WL) 134 is coupled to the gate 120 of the access PMOS transistor 104.

In the illustrated implementation, the coupling capacitor 128 and the ferroelectric capacitor 130 are coupled in series with each other. As a result, the total capacitance of the negative capacitor coupling gate 132 is amplified. The coupling ratio between the coupling capacitor 128 and the floating gate 112 also is increased. Moreover, using the negative capacitor coupling gate 132 the program and/or erase voltages for the cell 100 can be reduced.

In one or more implementations, the ferroelectric capacitor 130 includes at least one ferroelectric thin film. The fabrication of ferroelectric thin films that are compatible with silicon integrated circuit technology may be accomplished using low-temperature processing. Ferroelectric PbTiO3-based thin films may be fabricated at 723 degrees Kelvin by ultraviolet (UV)-rapid thermal processing (RTP) sol-gel processing. The gel film may be UV-irradiated at 523 degrees Kelvin, followed by a crystallization treatment at a non-detrimental temperature for the silicon substrate. The ferroelectric-paraelectric transition may occur at approximately 594 degrees Kelvin.

The low-temperature processing method used for integration of ferroelectrics into the semiconductor technology may provide microelectronic devices with similar performances of films processed at higher temperatures. In one or more alternative implementations, the ferroelectric film also may be a doped HfO2 film with laser anneal. The anneal temperature may be reduced to obtain a negative ferroelectric negative capacitor effect. In some implementations, e.g., the doped HfO2 ferroelectric capacitor, the substrate film may be omitted.

In an alternative optional implementation, the negative capacitor coupling gate 132 may include a dielectric capacitor 129 (i.e., an inter-plate dielectric capacitor). In one or more implementations, the dielectric capacitor 129 is a substrate for the film for the ferroelectric capacitor 130.

### Example 3T PMOS MTP Cell

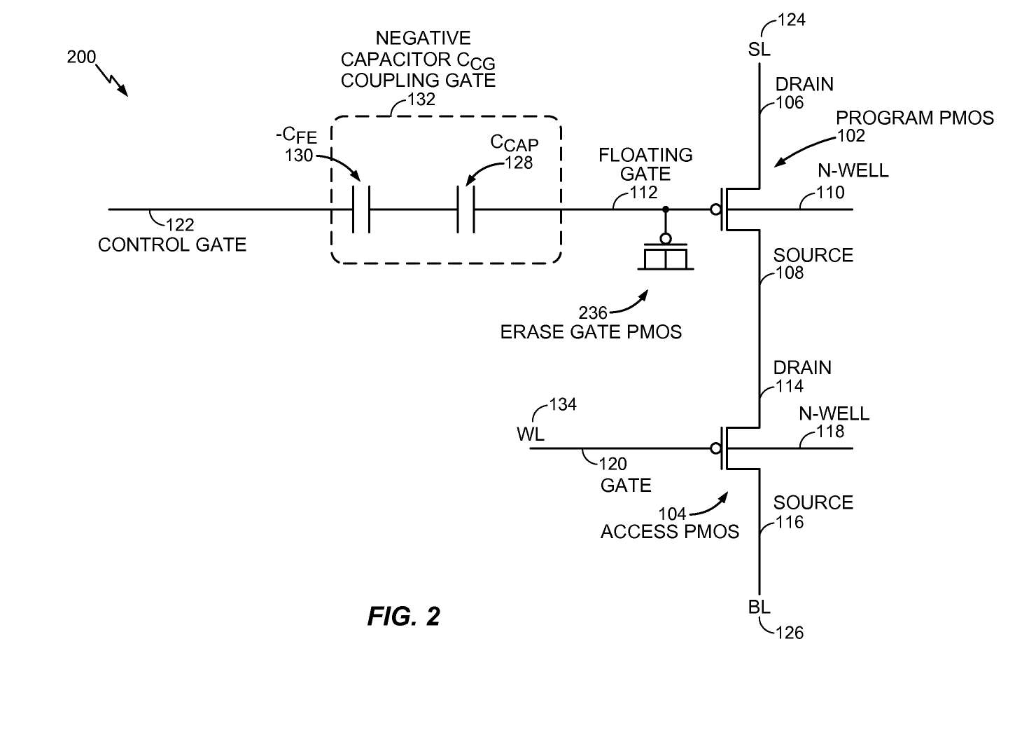

FIG. 2 is a schematic diagram of a three-transistor (3T) p-channel metal-oxide-semiconductor (PMOS) cell 200 of a Multiple Time Programmable (MTP) device according to an example implementation of the technology described herein. The cell 200 is similar to the cell 100, and like numbers represent like components. The cell 200 departs from the cell 100 in that a third transistor, an erase gate PMOS transistor 236, is coupled in parallel with the floating gate 112 and the negative capacitor coupling gate 132.

### Example 2T NMOS MTP Cell

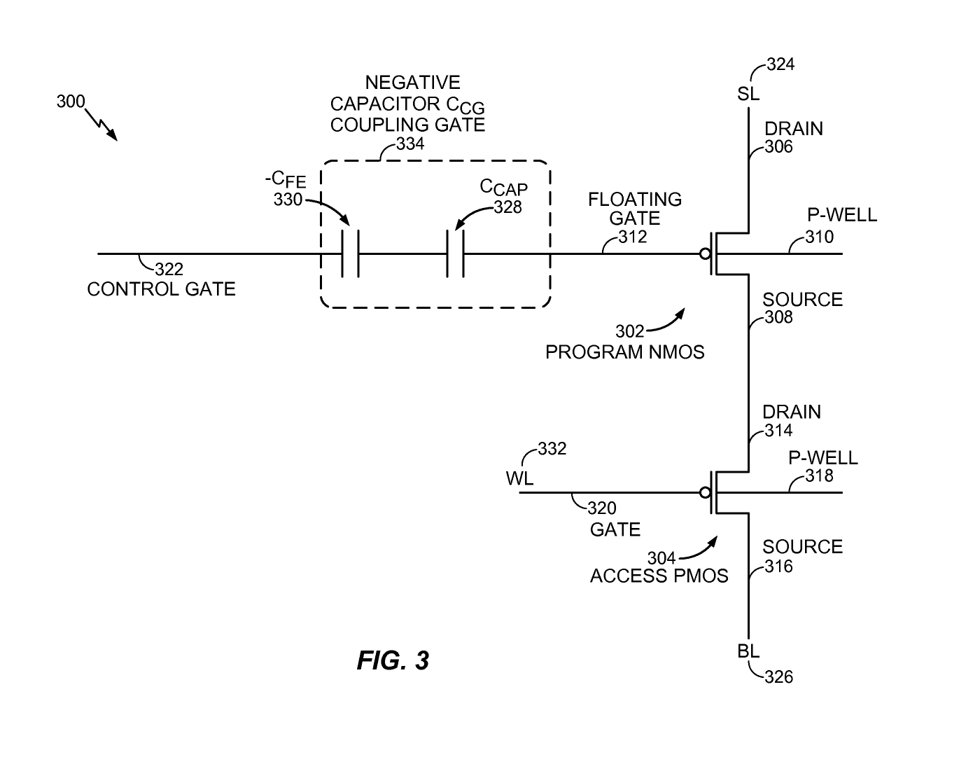

FIG. 3 is a schematic diagram of a two-transistor (2T) n-channel metal-oxide-semiconductor (NMOS) cell 300 of a Multiple Time Programmable (MTP) device according to an example implementation of the technology described herein. In one or more implementations, the cell 300 also may be implemented in a ferroelectric control gate MTP device and incorporated in systems where power conservation is a consideration, such as embedded memory applications for mobile devices. In one or more implementations, the cell 300 can be an N metal gate with an N channel. Alternatively, in one or more implementations, the cell 300 can be a P metal gate with an N channel.

The illustrated cell 300 includes a program NMOS transistor 302 and an access NMOS 304. The program NMOS 302 includes a drain 306, a source 308, and p-well 310, and a floating gate 312. The access NMOS transistor 304 includes a drain 314, a source 316, a p-well 318, and a gate 320. The cell 300 also includes a control gate 322, a source line (SL) 324, and a bit line (BL) 326. A coupling capacitor 328 and a ferroelectric capacitor 330 form a negative capacitor coupling gate 332. A word line (WL) 334 is coupled to the gate 320 of the access NMOS transistor 304.

In the illustrated implementation, the coupling capacitor 328 and the ferroelectric capacitor 330 are coupled in series with each other. As a result, the total capacitance of the negative capacitor coupling gate 332 is amplified. The coupling ratio between the coupling capacitor 328 and the floating gate 312 also is increased. Moreover, using the negative capacitor coupling gate 332 the program and/or erase voltages for the cell 300 can be reduced.

### Example 3T NMOS MTP Cell

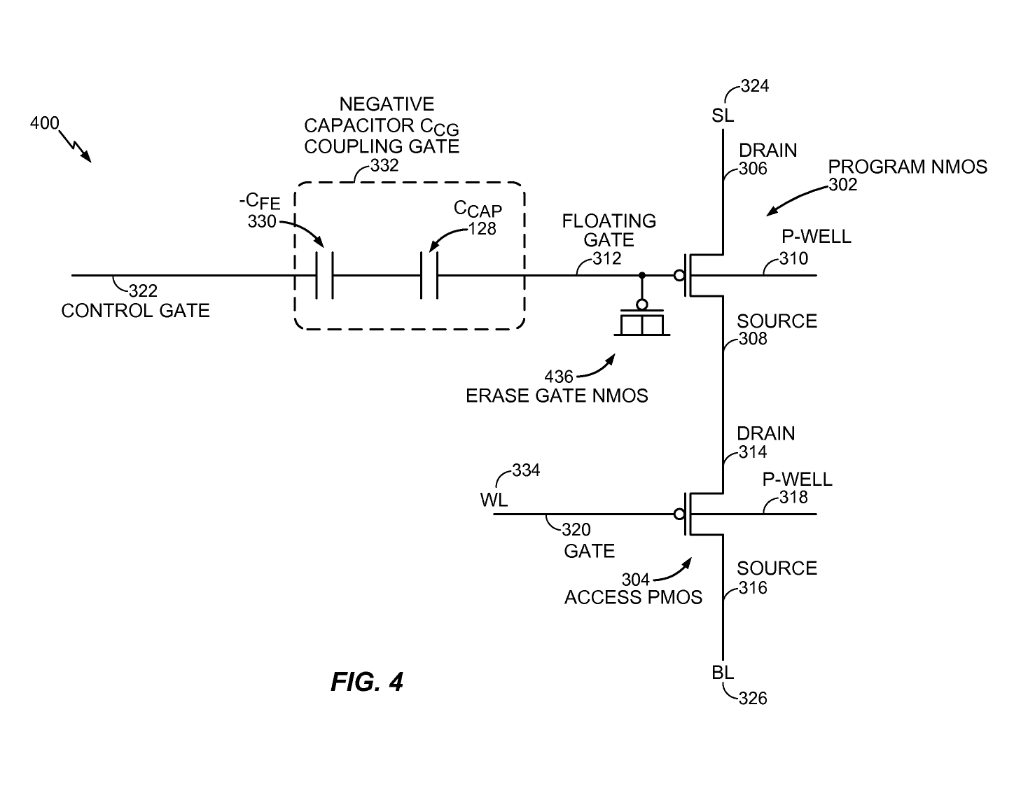

FIG. 4 is a schematic diagram of a three-transistor (3T) n-channel metal-oxide-semiconductor (NMOS) cell 400 of a Multiple Time Programmable (MTP) device according to an example implementation of the technology described herein. The cell 400 is similar to the cell 300, and like numbers represent like components. The cell 400 departs from the cell 300 in that a third transistor, an erase gate NMOS transistor 436 is coupled in parallel with the floating gate 312 and the negative capacitor coupling gate 332.

During fabrication of the Multiple Time Programmable (MTP) device, there may be only one ferroelectric film deposition step, which shares a mask with high resistance masks. Thusly, the cost addition for the fabrication may be minimal.

In one or more implementations, the word line device may be an input/output (I/O) device and the floating device may be an input/output (I/O) device or a core device. Additionally, error-correcting code (ECC) (e.g., error checking and correction) and/or auto repair techniques may be used to detect and correct data errors, refresh data, and improve data retention. The floating gate may be an input/output (I/O) type floating gate/p-channel. In this implementation, coupling efficiency may be better than in conventional devices. Data retention may be improved for less tunneling loss but programming may be slower. If the floating gate is a core floating gate, programming may be easier, but data retention may be worsened due to more tunneling loss. Using error-correcting code (ECC) and auto-repair techniques, data retention may be improved.

Example Cross-Sectional Views of MTP Devices with P+ Contacts in N-Well

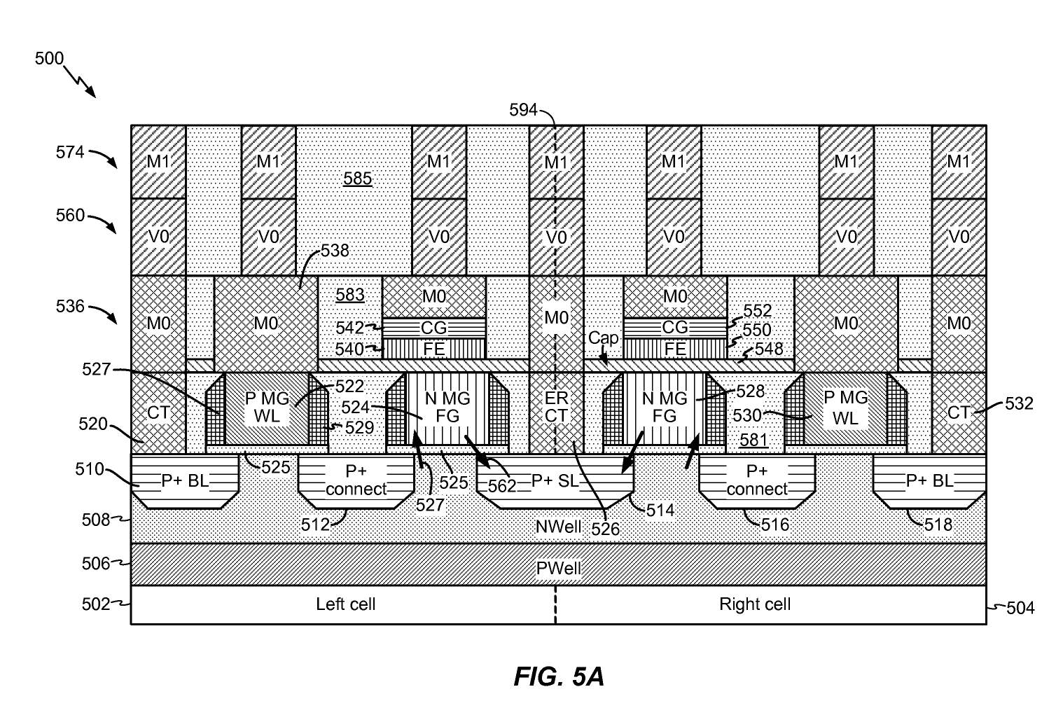

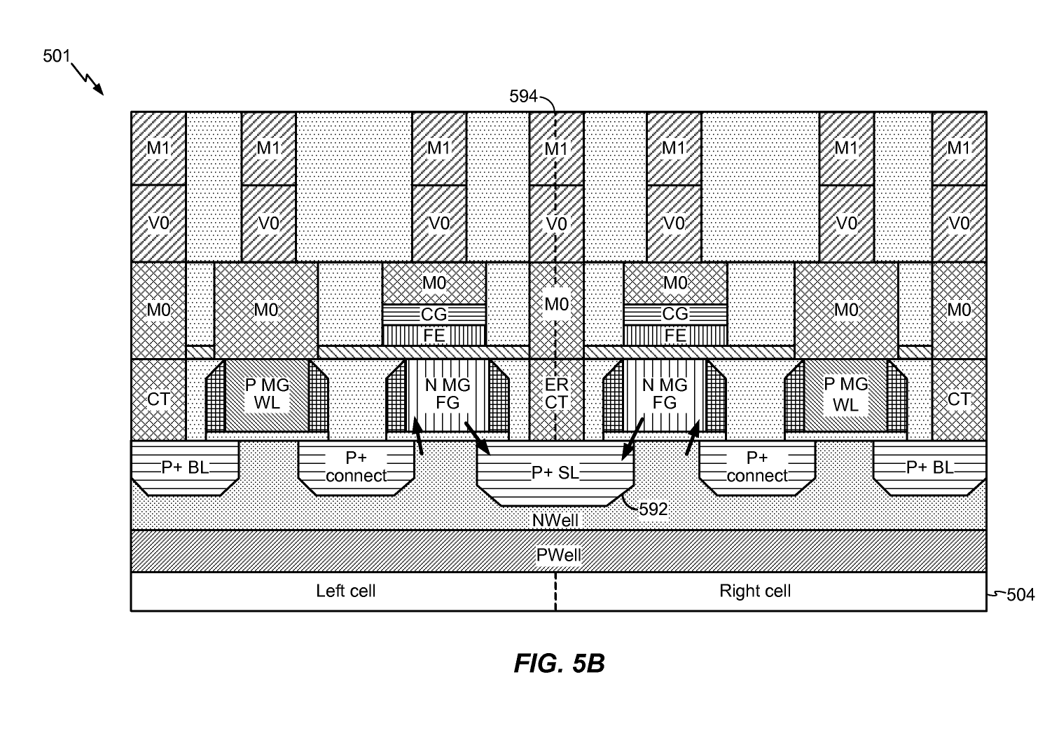

FIG. 5A is cross-sectional views of a Multiple Time Programmable (MTP) device 500 according to an example implementation of the technology described herein. The device 500 may be a high-k metal gate n-gate/p-channel Multiple Time Programmable (MTP) device.

The illustrated device 500 includes a left cell 502, a right cell 504, a p-well 506 formed on the left cell 502, and the right cell 504. An n-well 508 is formed on the p-well 506.

Several source or drain regions are formed in the n-well 508. As illustrated, a P+ bit line source region 510, a P+ drain contact 512, a P+ source line contact 514, a P+ drain contact 516, and a P+ bit line contact 518 are formed in the n-well 508. A contact CT 520 is formed on the P+ bit line contact 510.

The device 500 includes a P metal gate 522 for the word line in the left cell 502, an N metal gate 524 for a floating gate in the left cell 502, an erase contact 526 shared by the left cell 502 and the right cell 504, an N metal gate 528 for the floating gate in the right cell 504, a P metal gate 530, contact 532 in the right cell 504. The P metal gate 522 for the word line in the left cell 502, an N metal gate 524, erase contact 526, N metal gate 528, and the P metal gate 530 each are formed on a gate oxide material 525 that is formed on the source and drain regions and the n-well 508. Each metal gate has two sidewalls, sidewalls 527 and 529, for example. An oxide layer 581 separates the metal gates 522 and 524 from each other. The oxide layer 581 also separates metal gates 528 and 530 from each other. The oxide layer also separates the erase gate contact 526 from the metal gates 524 and 528.

A layer 0 metal layer (M0) 536 is formed in the device 500. Portions of the layer 0 metal layers (M0) 536 are formed on a capacitor dielectric 548 (e.g. inter-plate dielectric (IPD) capacitor), which may be the coupling capacitor 128 and/or 328. Ferroelectric capacitors 540 and 550, which may be the ferroelectric capacitor 130 and/or 330, are formed on the capacitor dielectric 548.

Control gates 542 and 552, which may be control gates 122 and/or 322, are formed on the ferroelectric capacitors 540 and 550. Portions of the metal layer 0 (M0) 536 are formed on control gates 542 and 552. Portions of the layer 0 metal layer (M0) 536 are formed on the erase contact 526. An oxide layer 583 separates the individual portions of the layer 0 metal layer (M0) 536.

A via0 560 is formed on the layer 0 metal layer (M0) 536. Individual portions of the via0 560 are separated from each other using an oxide material 585.

A layer 1 metal layer (M1) 574 is formed on the via0 560. The Layer 1 metal layers (M1) 574 are formed on the via0 560 are separated from each other using the oxide material 585.

An arrow 527 indicates the direction of the flow of charge carriers in the left cell 502 during programming operations of the device 500. An arrow 562 indicates the direction of the flow of charge carriers in the left cell 502 during erasing operations of the device 500. Charge carriers move similarly in the right cell 504.

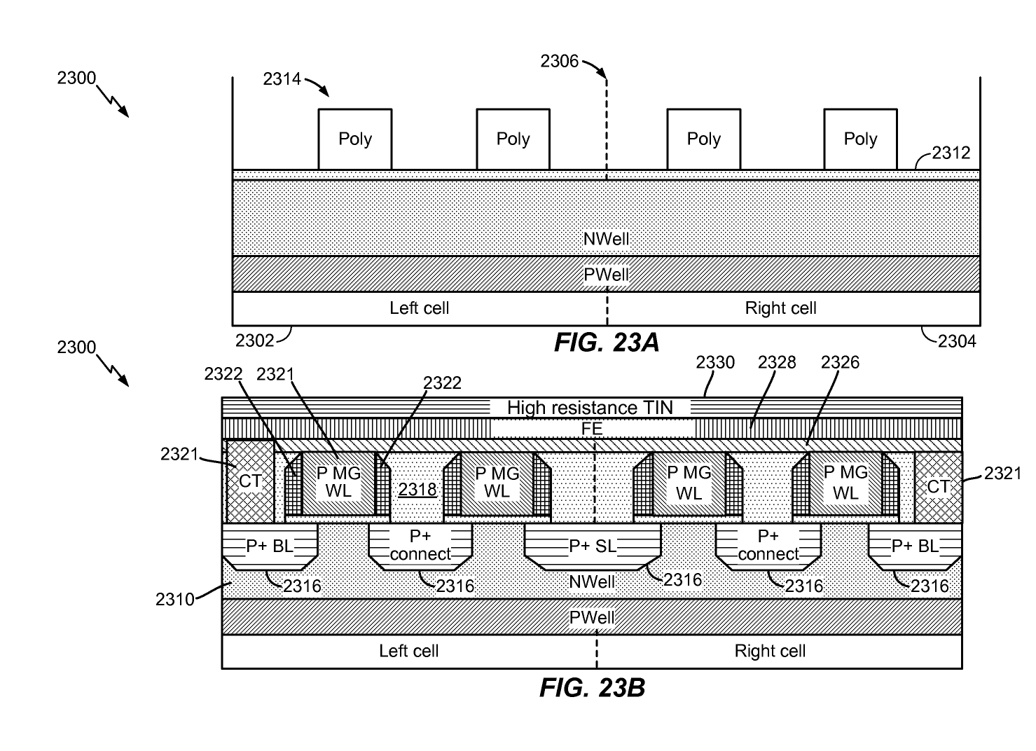

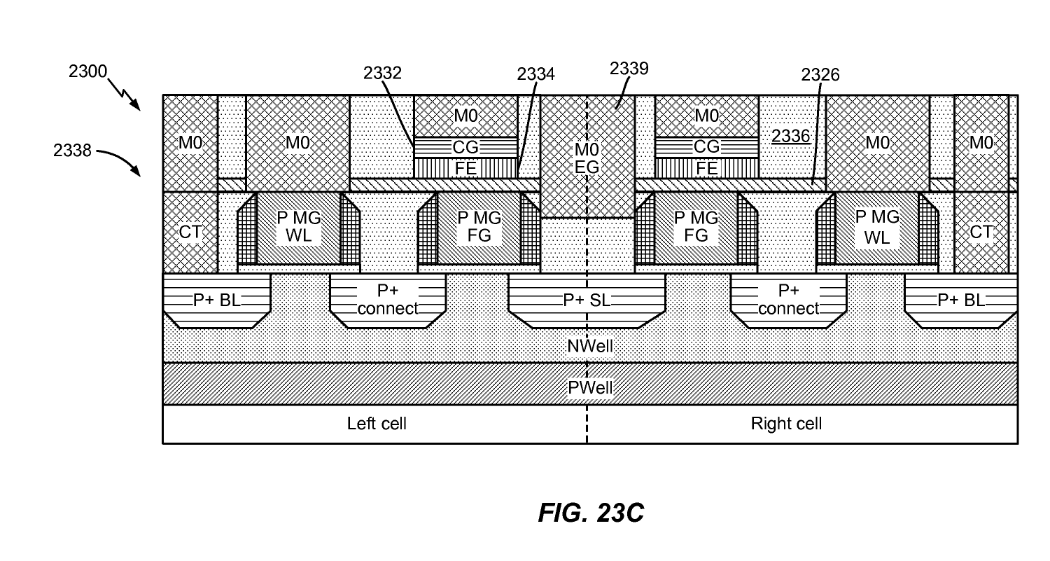

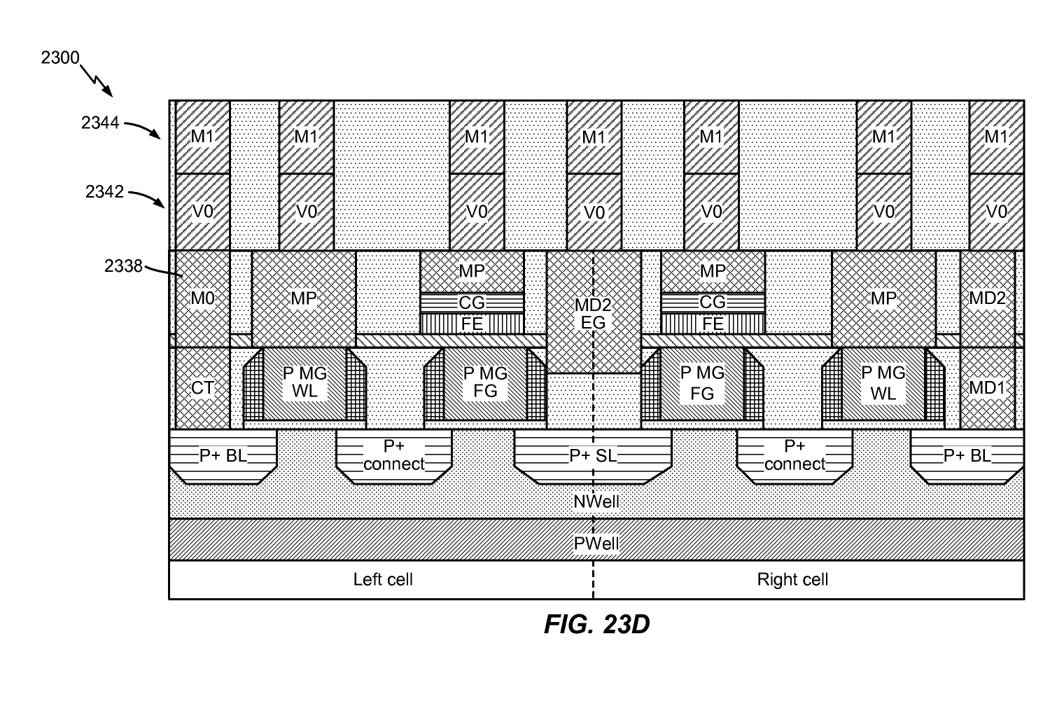

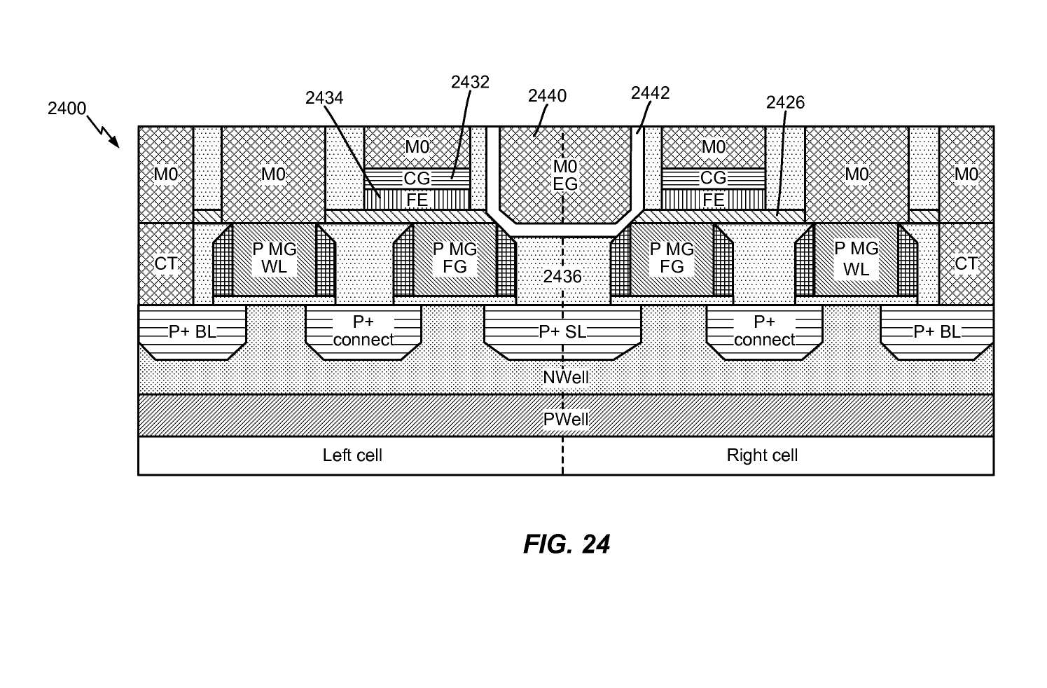

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim tunneling. No additional process steps are used in fabricating the device. The endurance performance of the bit cell may be limited, however. That is, the cycling or the number of times that the bit cell may be written may be limited. The process for manufacturing implementations of the technology described herein is discussed below with reference to FIGS. 23(a) through 24.

FIG. 5B is cross-sectional views of the Multiple Time Programmable (MTP) device 501 according to example alternative implementations of the technology described herein. The device 501 illustrated in FIG. 5(b) is similar to the device 500 illustrated in FIG. 5A except that the P+ source line source region 592 is a deep well source region.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim (F-N) tunneling. Also, one deep source mask is added to improve programming and reduce the potential for drain disturb. Endurance may be limited, however.

Note that FIGS. 5A and 5B illustrate a left cell 502 and a right cell 504 as having N metal gate 524 and 528. However, implementations are not so limited.

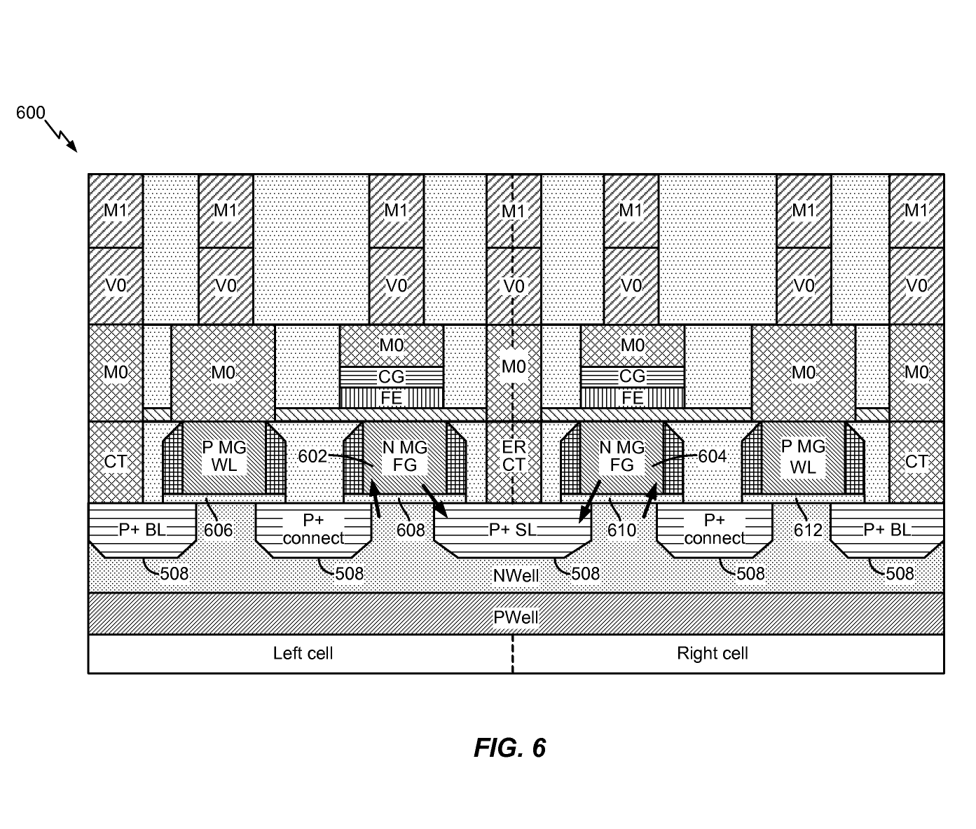

For example, FIG. 6 is a cross-sectional view of a Multiple Time Programmable (MTP) device 600 according to an example implementation of the technology described herein. The device 600 may be a high-k metal gate PMOS Multiple Time Programmable (MTP) device.

In the illustrated implementation, a left cell and a right cell include P metal gates for floating gates 602 and 604 instead of N metal gates.

The coupling gate in this implementation also is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim (F-N) tunneling. No additional process steps are used; however endurance performance of the bit cell may be limited.

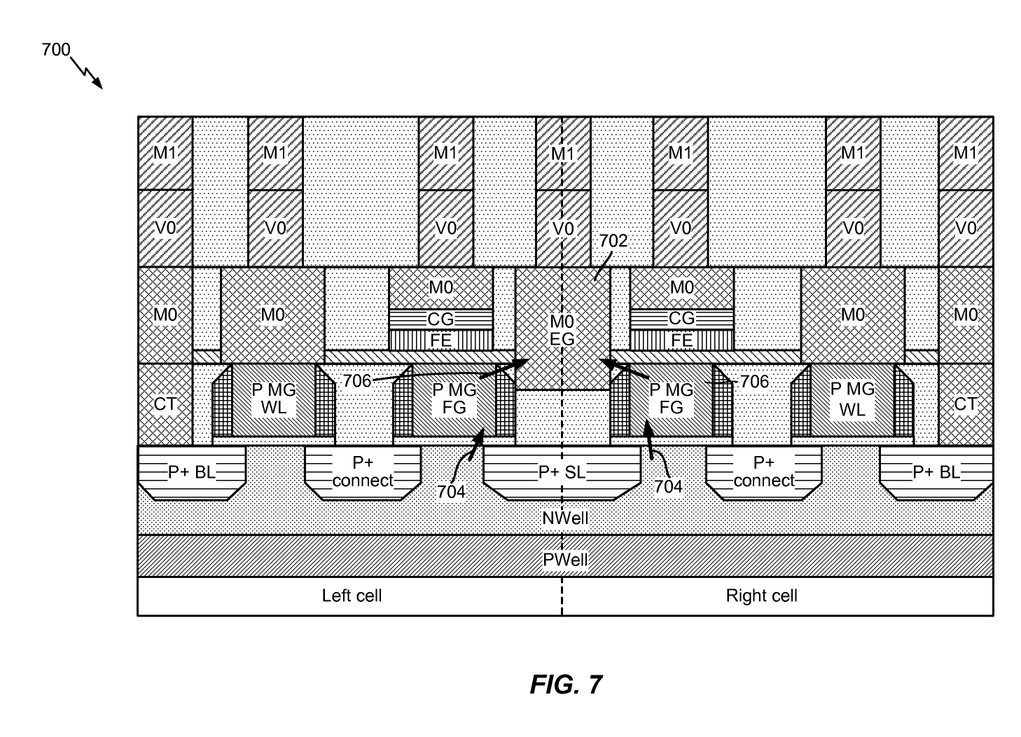

FIG. 7 is a cross-sectional view of a Multiple Time Programmable (MTP) device 700 according to an example implementation of the technology described herein that is similar to the device 600 except that an erase gate and a portion of the layer 0 metal layer (M0) is combined into a separate element 702. The device 700 may be a high-k metal gate PMOS Multiple Time Programmable (MTP) device.

An arrow 704 indicates the direction of the flow of charge carriers during programming operations of the device 700. An arrow 706 indicates the direction of the flow of charge carriers during erasing operations of the device 700.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using erase gate dielectric Fowler-Nordheim (F-N) tunneling. No additional process steps are used; however erase performance of the bit cell may suffer.

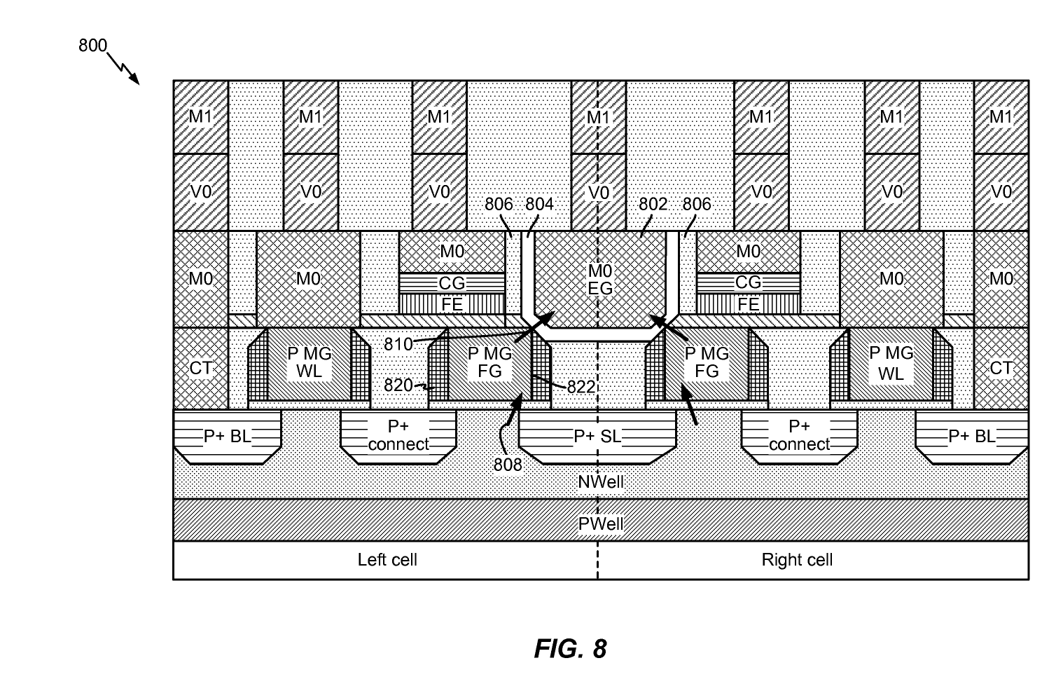

FIG. 8 is a cross-sectional view of a Multiple Time Programmable (MTP) device 800 according to an example implementation of the technology described herein that is similar to the device 700 except that a combined an erase gate and a portion of the layer 0 metal layer (M0) (M0 EG) 802 is a different shape and a dielectric material 804 is disposed between the combined an erase gate and a portion of the layer 0 metal layer (M0) 802 and an oxide spacer 806. The device 800 may be a high-k metal gate PMOS Multiple Time Programmable (MTP) device.

An arrow 808 indicates the direction of the flow of charge carriers during programming operations of the device 800. An arrow 810 indicates the direction of the flow of charge carriers during erasing operations of the device 800.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric Fowler-Nordheim (F-N) tunneling. The metal gate tip enhances tunneling. Also the process for the illustrated implementation adds the M0 EG mask for erase gate patterning and oxide deposition before metal layer (M0) patterning.

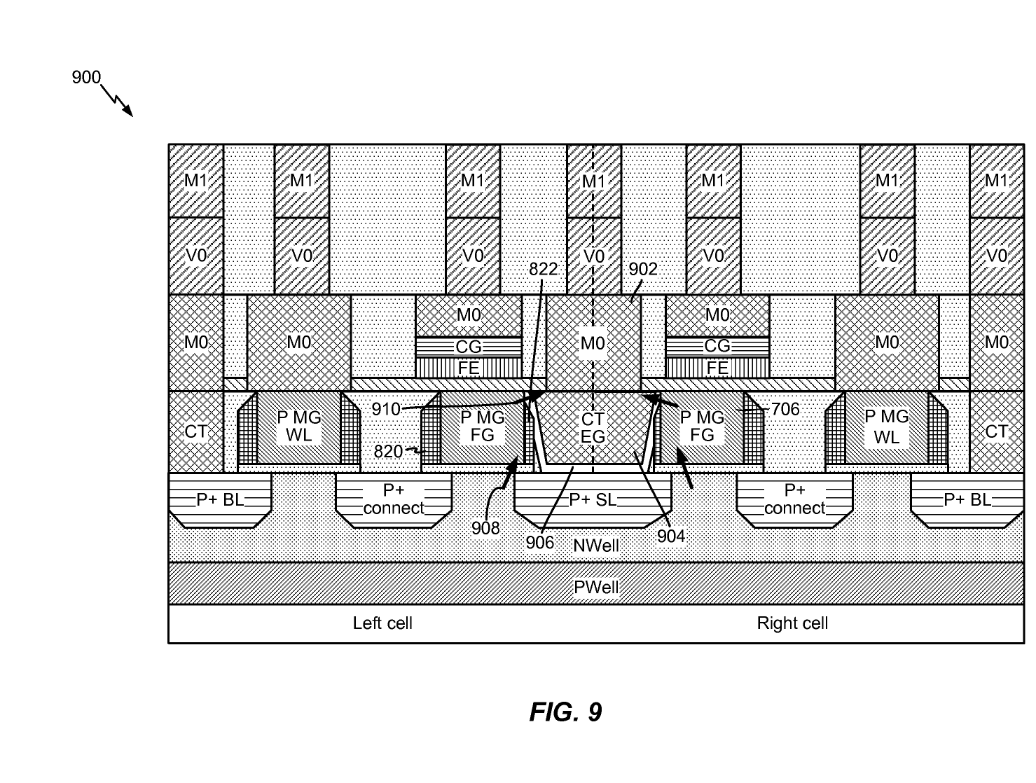

FIG. 9 is a cross-sectional view of a Multiple Time Programmable (MTP) device 900 according to an example implementation of the technology described herein that is similar to the device 800 except that the combined an erase gate has been separated from a portion of the layer 0 metal layer (M0) 902 and a portion of the sidewall 822 has been trimmed away. Moreover, an erase gate contact 904 of a different shape is disposed in a dielectric material 906. The dielectric material 804 around the portion of the layer 0 metal layer (M0) 902 has been removed. The device 800 may be a high-k metal gate PMOS Multiple Time Programmable (MTP) device.

An arrow 908 indicates the direction of the flow of charge carriers during programming operations of the device 900. An arrow 910 indicates the direction of the flow of charge carriers during erasing operations of the device 900.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric corner Fowler-Nordheim (F-N) tunneling. The process for the illustrated implementation adds the erase gate contact (CT EG) mask/oxide etch and spacer removal before contact patterning.

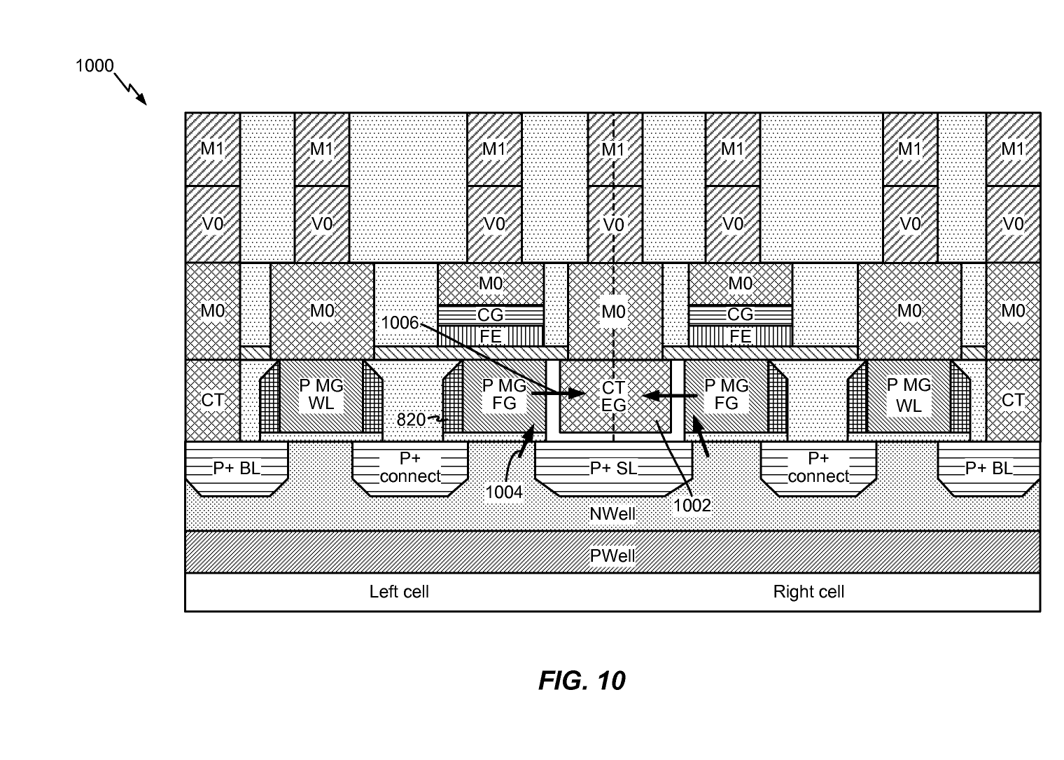

FIG. 10 is a cross-sectional view of a Multiple Time Programmable (MTP) device 1000 according to an example implementation of the technology described herein that is similar to the device 900 except that an erase gate contact 1002 of a different shape is disposed in a dielectric material and substantially all of the sidewall 822 has been trimmed away. The device 1000 may be a high-k metal gate PMOS Multiple Time Programmable (MTP) device.

An arrow 1004 indicates the direction of the flow of charge carriers during programming operations of the device 1000. An arrow 1006 indicates the direction of the flow of charge carriers during erasing operations of the device 1000.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric corner Fowler-Nordheim (F-N) tunneling. The process for the illustrated implementation adds the erase gate contact (CT EG) mask/oxide etch and spacer removal before CT contact patterning.

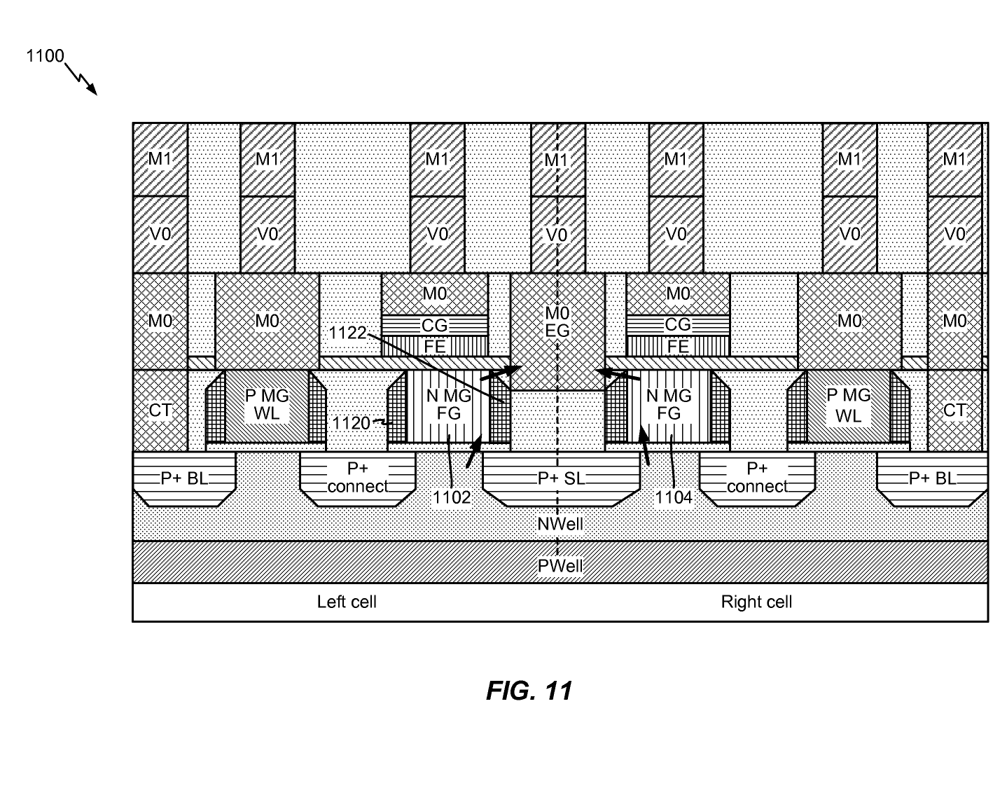

FIG. 11 is a cross-sectional view of a Multiple Time Programmable (MTP) device 1100 according to an example implementation of the technology described herein that is similar to the device 700 except that the P metal gates of the device 700 have been replaced by N metal gates 1104 and 1106. The device 1100 may be a high-k metal gate n-gate/p-channel Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an n-gate/p-channel input/output (I/O) type interface. The associated bit cell is erased using metal gate-to-erase gate dielectric Fowler-Nordheim (F-N) tunneling. The metal gate tip enhances tunneling. Also in the process for the illustrated implementation, no additional process steps are used. However erase performance of the bit cell may suffer.

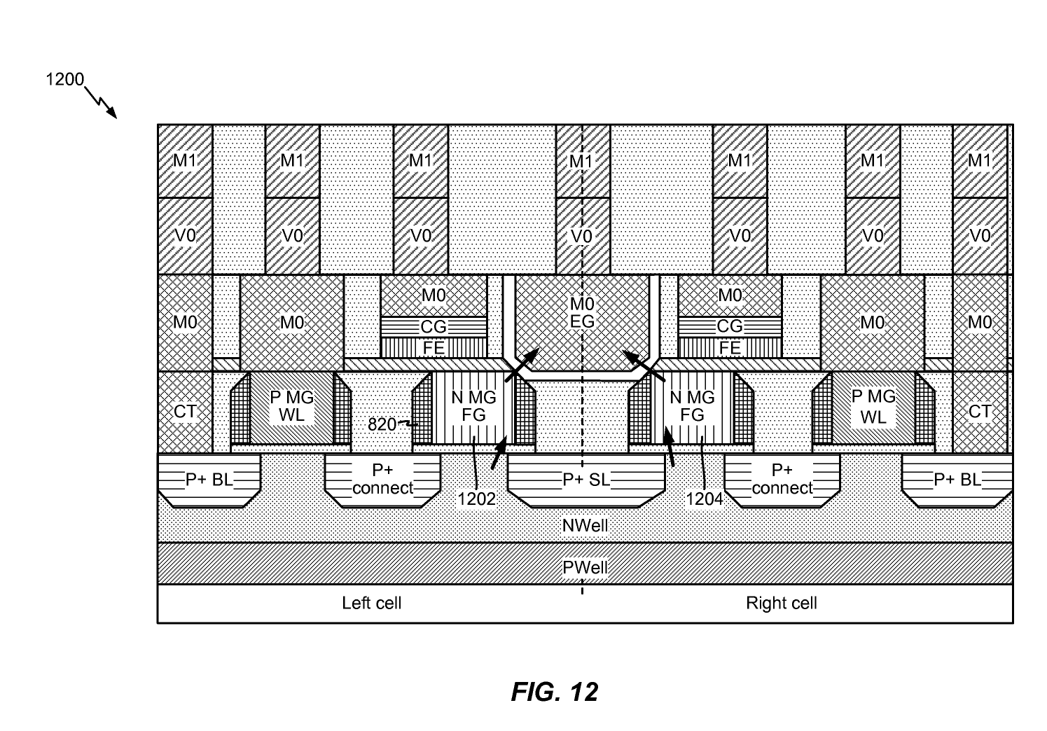

FIG. 12 is a cross-sectional view of a Multiple Time Programmable (MTP) device 1200 according to an example implementation of the technology described herein that is similar to the device 800 except that the P metal gates of the device 800 have been replaced by N metal gates 1202 and 1204. The device 1200 may be a high-k metal gate n-metal gate/p-channel Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an n-gate/p-channel input/output (I/O) type interface. The associated bit cell is erased using metal gate-to-erase gate dielectric Fowler-Nordheim (F-N) tunneling. The metal gate tip enhances tunneling. Also the process for the illustrated implementation adds the M0 EG mask for erase gate patterning and oxide deposition before metal layer (M0) patterning.

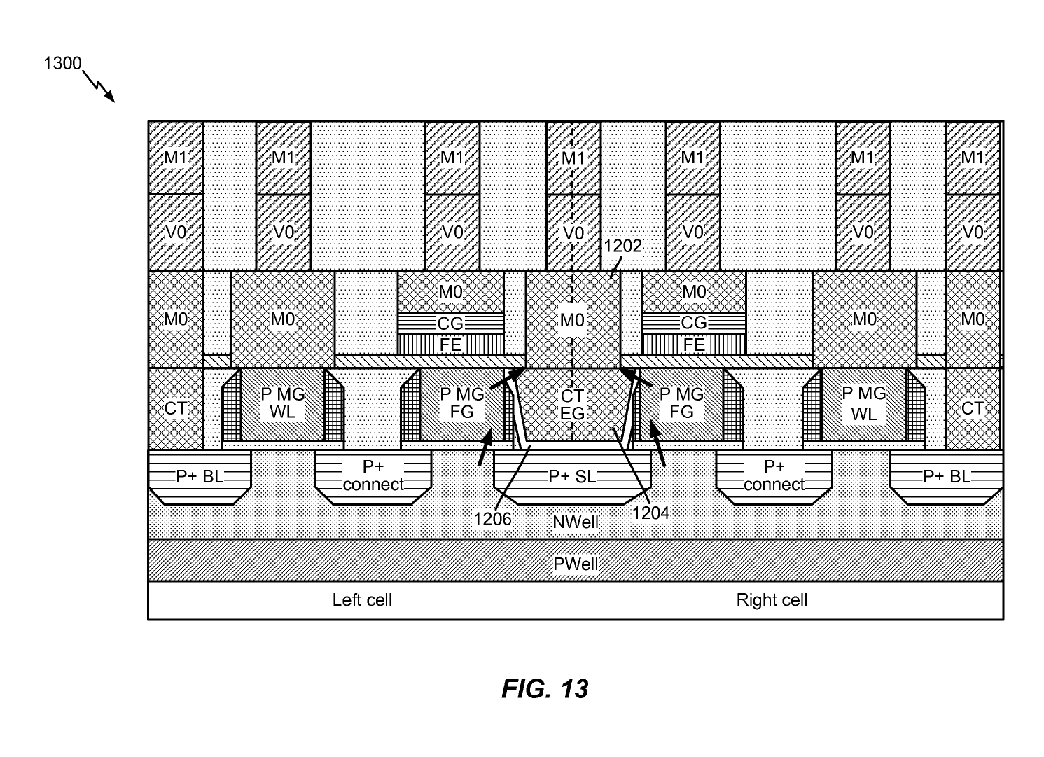

FIG. 13 is a cross-sectional view of a Multiple Time Programmable (MTP) device 1300 according to an example implementation of the technology described herein that is similar to the device 900 except that the P metal gates of the device 900 have been replaced by N metal gates 1202 and 1204. The device 1300 may be a high-k metal gate n-metal gate/p-channel Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an n-gate/p-channel input/output (I/O) type interface. The associated bit cell is erased using metal gate-to-erase gate dielectric corner Fowler-Nordheim (F-N) tunneling. The process for the illustrated implementation adds the erase gate contact (CT EG) mask for erase gate patterning and oxide deposition before contact patterning.

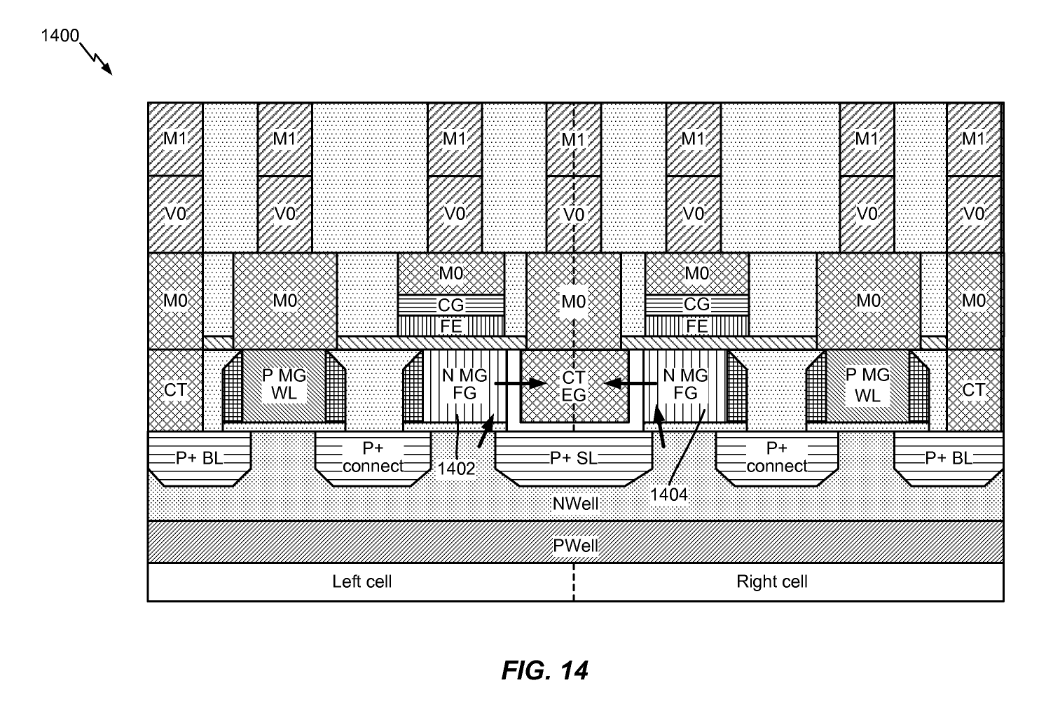

FIG. 14 is a cross-sectional view of a Multiple Time Programmable (MTP) device 1400 according to an example implementation of the technology described herein that is similar to the device 1000 except that the P metal gates of the device 1000 have been replaced by N metal gates 1402 and 1404. The device 1400 may be a high-k metal gate n-metal gate/p-channel Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an n-gate/p-channel input/output (I/O) type interface. The associated bit cell is erased using metal gate-to-erase gate dielectric corner Fowler-Nordheim (F-N) tunneling. The process for the illustrated implementation adds the erase gate contact (CT EG) mask/oxide etch and spacer removal before CT contact patterning.

Table 1 below illustrates the operation of the PMOS devices described herein according to one or more implementations. Vp1 and Vp2 represent the program voltages. Ve represents the erase voltage. V_{REF} represents the reference voltage for the bit cell sensed voltage comparison.

TABLE 1
PMOS MTP Operation

| Terminate | Operation | Read | Program | Erase |
|---|---|---|---|---|
| Word Line | Selected | 0 V | V_{CC} | V_{CC} |
| | Unselected | V_{CC} | 0 V | V_{CC} |
| Source Line | Selected | V_{CC} | Vp1 (1~3 V) | 0 V |
| | Unselected | V_{CC} | 0 V | 0 V |
| Coupling Gate | Selected | V_{CC} | Vp2 (~−5 V) | ~−5 V |
| | Unselected | 0 V | 0 V | 0 V |
| Erase Gate | Selected | 0 V | Vp1 (1~3 V) | Ve (~6 V) |
| | Unselected | 0 V | 0 V | 0 V |
| Bit Line | Selected | V_{REF} | <1 V | 0 V |
| | Unselected | V_{REF} | V_{CC} | 0 V |

Example Cross-Sectional Views of MTP Devices with N+ Contacts in P-Well

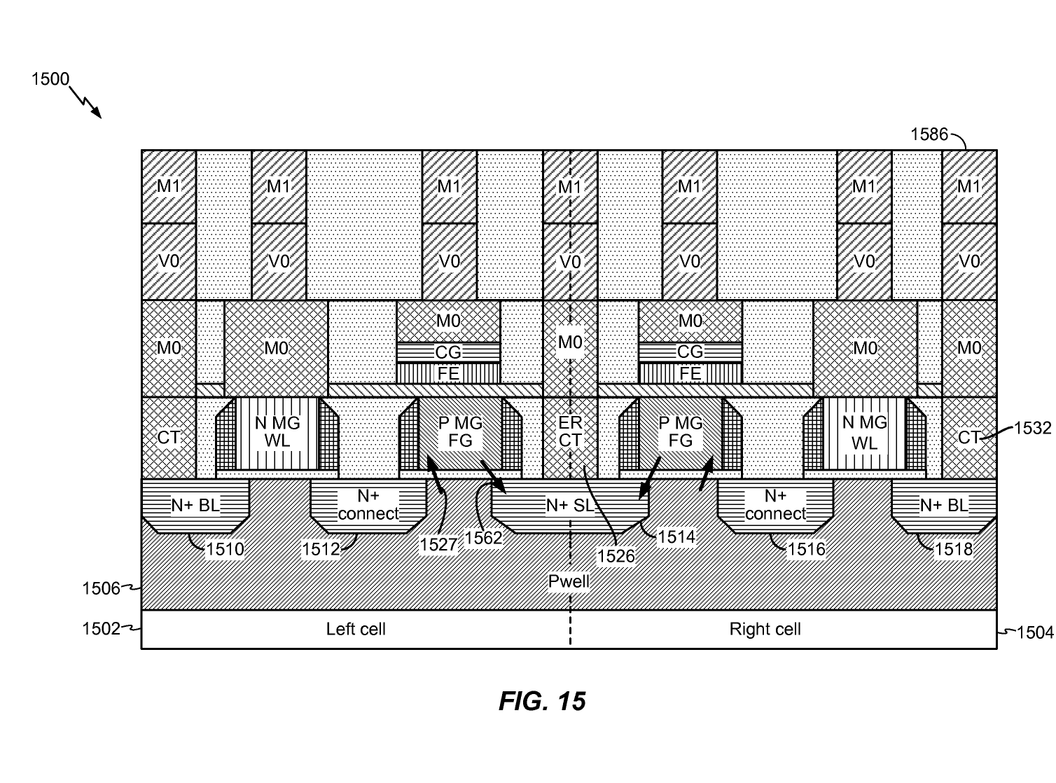

FIG. 15 is a cross-sectional view of a Multiple Time Programmable (MTP) device 1500 according to an example implementation of the technology described herein that is similar to the device 500 except that an N+ bit line source region 1510, an N+ drain region 1512, an N+ source line region 1514, an N+ drain region 1516, and an N+ bit line source region 1518 are formed in a p-well 1506. The device 1500 may be a high-k metal gate n-metal NMOS Multiple Time Programmable (MTP) device.

An arrow 1527 indicates the direction of the flow of charge carriers during programming operations of the device 1500. An arrow 1562 indicates the direction of the flow of charge carriers during erasing operations of the device 1500.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim tunneling. No additional process steps are used; however endurance performance of the bit cell may be limited.

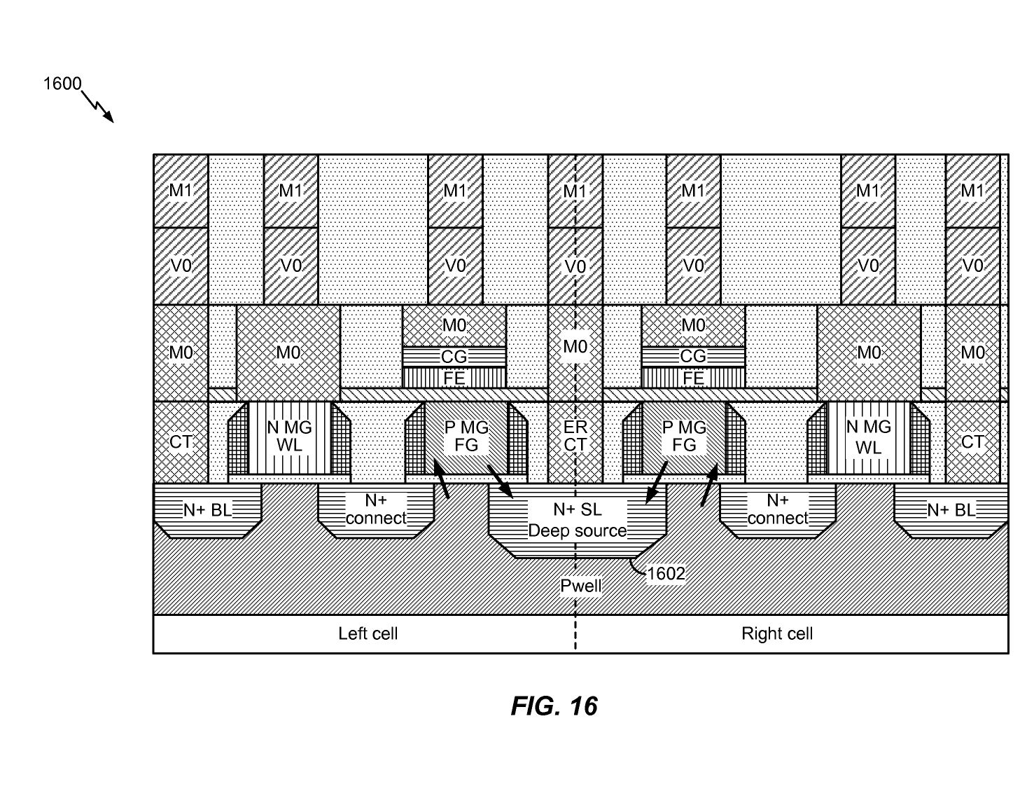

FIG. 16 is cross-sectional views of the Multiple Time Programmable (MTP) device 1600 according to example alternative implementations of the technology described herein. The device 1600 is similar to the device 1500 except that an N+ source line region 1602 is a deep source region. The device 1500 may be a high-k metal gate n-metal NMOS Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim (F-N) tunneling. Also, one deep source mask is added to improve programming, but endurance performance may be limited.

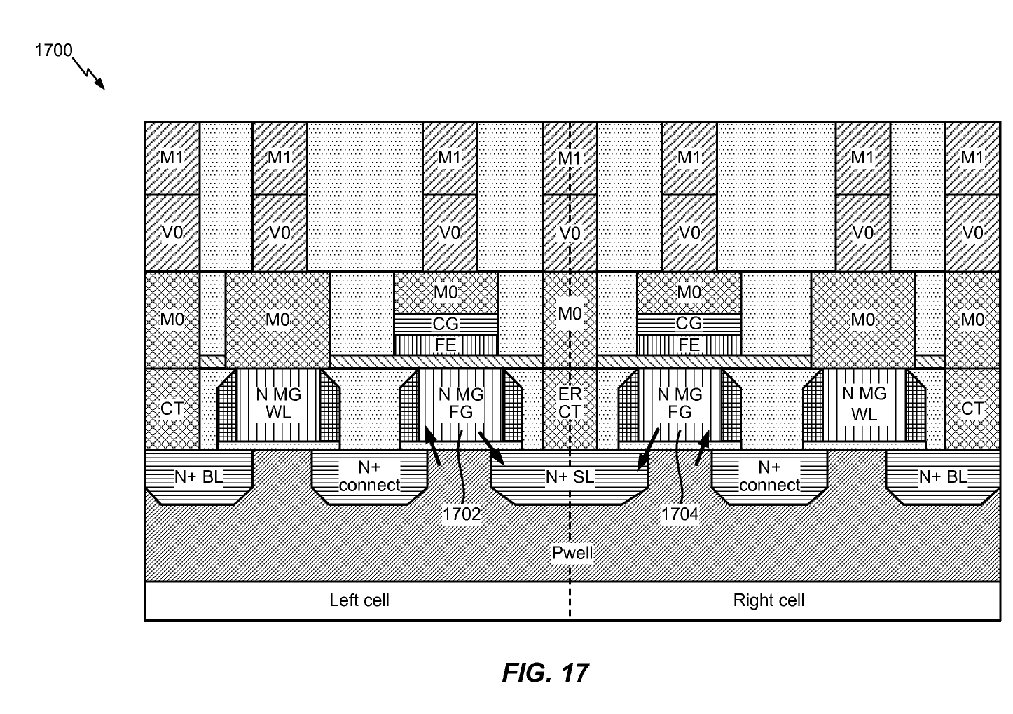

FIG. 17 is a cross-sectional view of a Multiple Time Programmable (MTP) device 1700 according to example implementations of the technology described herein. The device 1700 is similar to the device 1600 except that it has N metal gates 1702 and 1704 for its floating gates instead of P metal gates. The device 1500 may be a high-k metal gate n-metal NMOS Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim (F-N) tunneling. No additional process step is added, but endurance performance may be limited.

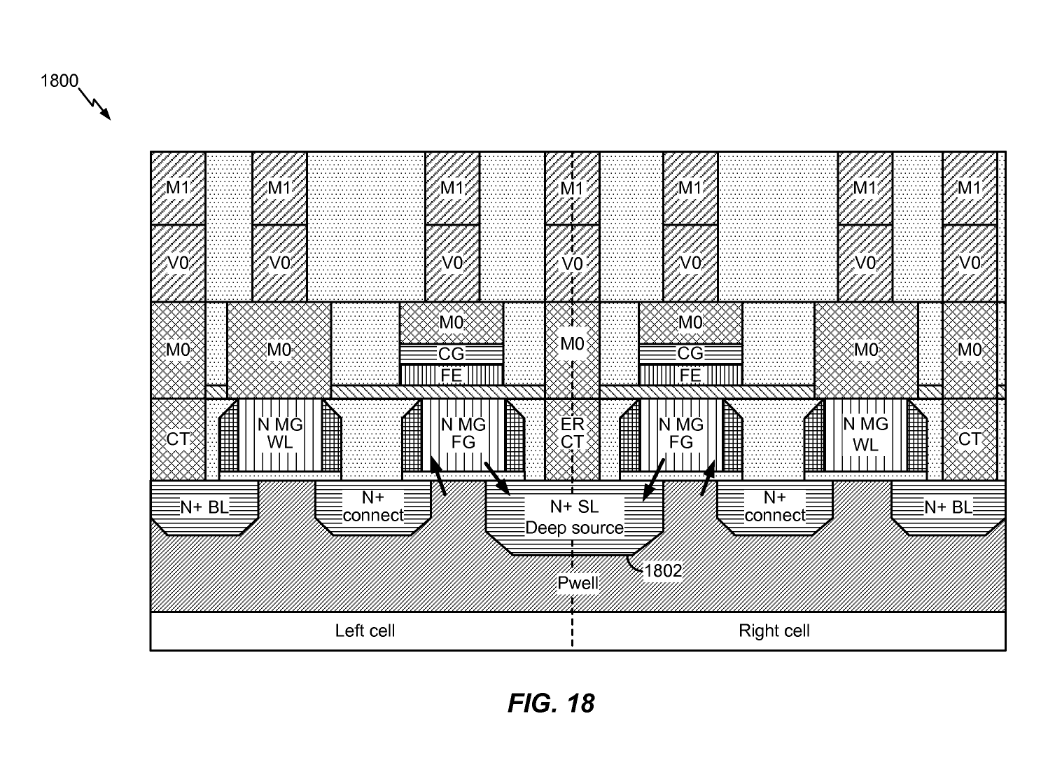

FIG. 18 is a cross-sectional view of a Multiple Time Programmable (MTP) device 1800 according to example implementations of the technology described herein. The device 1800 is similar to the device 1700 except that its n+ source line region 1802 is a deep source region. The device 1500 may be a high-k metal gate n-metal NMOS Multiple Time Programmable (MTP) device.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-source line gate dielectric Fowler-Nordheim (F-N) tunneling. Also, one deep source mask is added to improve programming, but endurance may be limited.

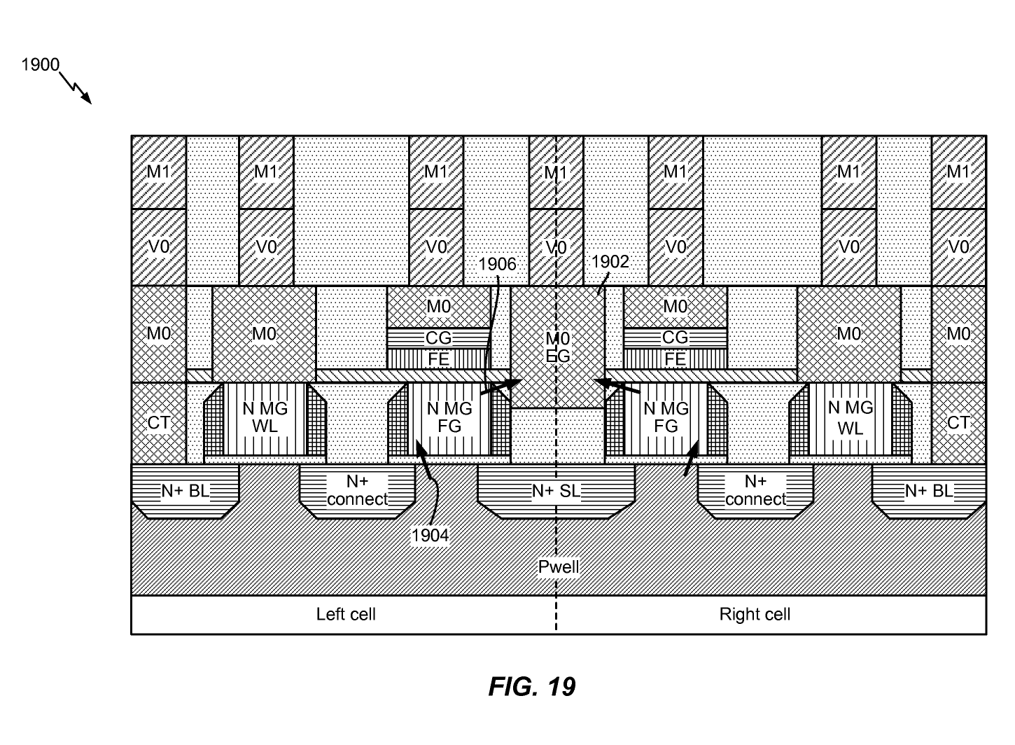

FIG. 19 is a cross-sectional view of a Multiple Time Programmable (MTP) device 1900 according to example implementations of the technology described herein. The device 1900 is similar to the device 1800 except that an erase gate and a portion of the layer 0 metal layer (M0) are combined into a separate element 1902. An arrow 1904 indicates the direction of the flow of charge carriers during programming operations of the device 1900. The device 1500 may be a high-k metal gate n-metal NMOS Multiple Time Programmable (MTP) device.

An arrow 1906 indicates the direction of the flow of charge carriers during erasing operations of the device 1900.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric Fowler-Nordheim (F-N) tunneling. No additional process steps are used. However erase performance of the bit cell may suffer.

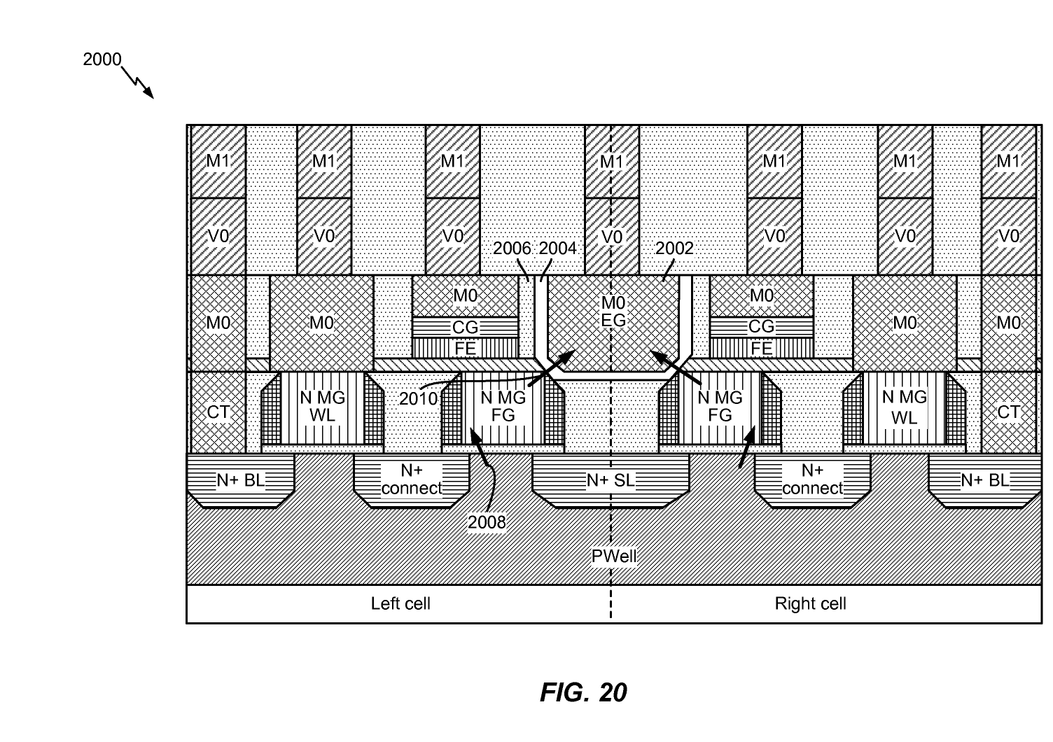

FIG. 20 is a cross-sectional view of a Multiple Time Programmable (MTP) device 2000 according to example implementations of the technology described herein. The device 2000 is similar to the device 1900 except that that a combined an erase gate and a portion of the layer 0 metal layer (M0) 2002 is a different shape and a dielectric material 2004 is disposed between the combined an erase gate and a portion of the layer 0 metal layer (M0) 2002 and an oxide spacer 2006. The device 1500 may be a high-k metal gate n-metal NMOS Multiple Time Programmable (MTP) device.

An arrow 2008 indicates the direction of the flow of charge carriers during programming operations of the device 2000. An arrow 2010 indicates the direction of the flow of charge carriers during erasing operations of the device 2000.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric Fowler-Nordheim (F-N) tunneling. The metal gate tip enhances tunneling. Also the process for the illustrated implementation adds the M0 EG mask for erase gate patterning and oxide deposition before metal layer (M0) patterning.

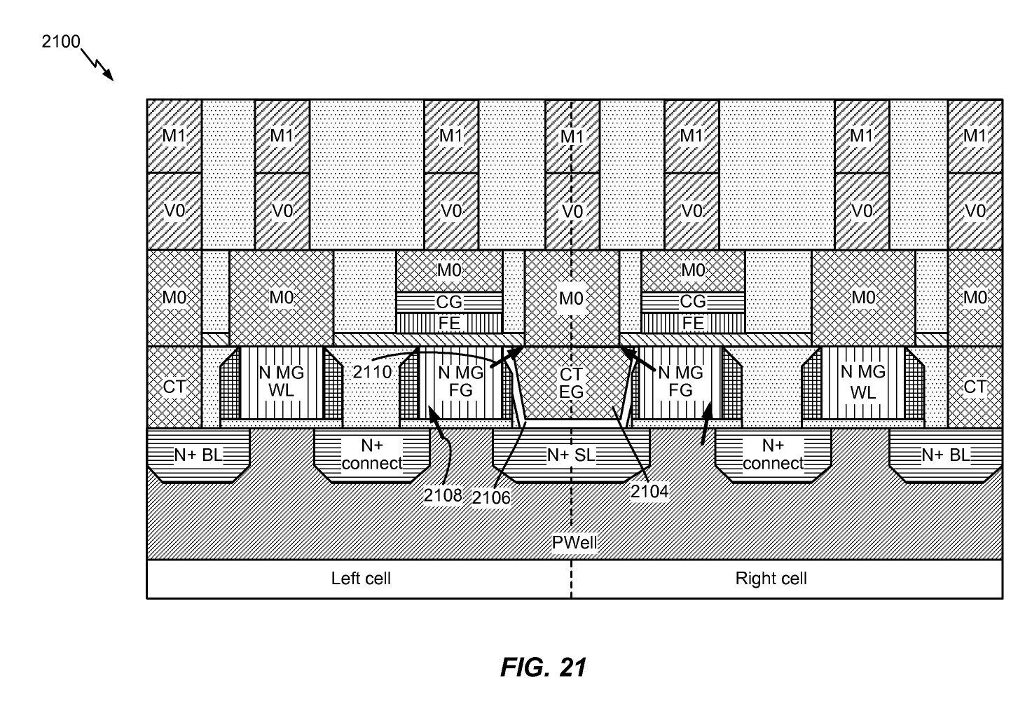

FIG. 21 is a cross-sectional view of a Multiple Time Programmable (MTP) device 2100 according to an example implementation of the technology described herein that is similar to the device 2000 except that the combined an erase gate has been separated from a portion of the layer 0 metal layer (M0) 2102. Moreover, an erase gate contact 2104 of a different shape is disposed in a dielectric material 2106. The dielectric material around the portion of the layer 0 metal layer (M0) 2102 has been removed. An arrow 2108 indicates the direction of the flow of charge carriers during programming operations of the device 2100. The device 1500 may be a high-k metal gate n-metal NMOS Multiple Time Programmable (MTP) device.

An arrow 2110 indicates the direction of the flow of charge carriers during erasing operations of the device 2100.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric corner Fowler-Nordheim (F-N) tunneling. The process for the illustrated implementation adds the erase gate contact (CT EG) mask for erase gate patterning and oxide deposition before contact patterning.

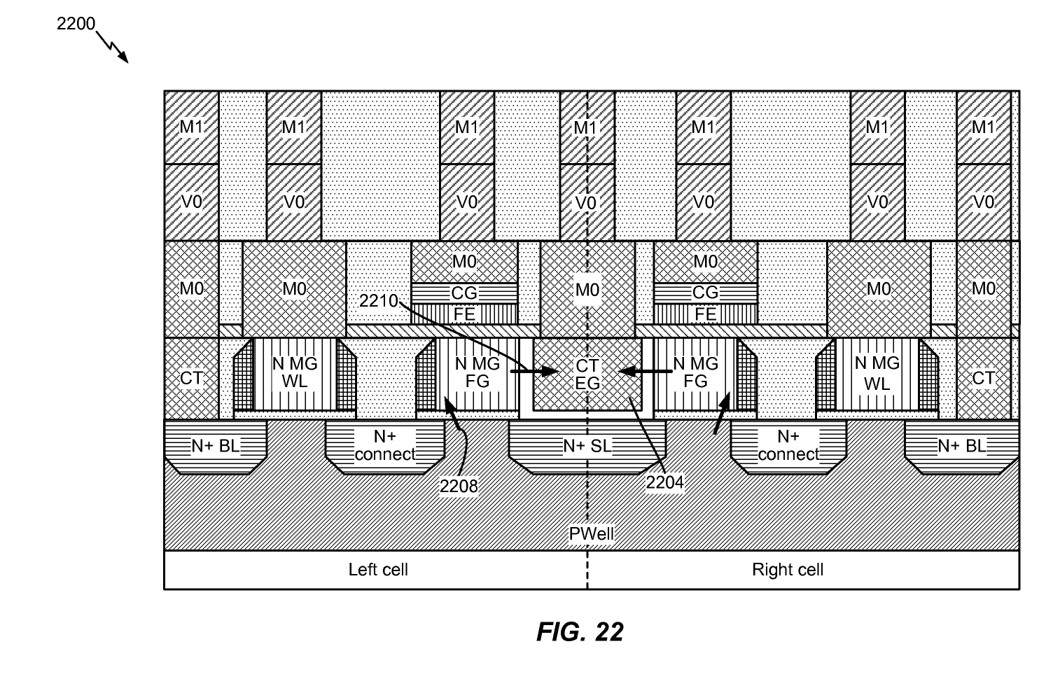

FIG. 22 is a cross-sectional view of a Multiple Time Programmable (MTP) device 2200 according to an example implementation of the technology described herein that is similar to the device 2100 except that an erase gate contact 2204 of a different shape is disposed in a dielectric material. The device 1500 may be a high-k metal gate n-metal NMOS Multiple Time Programmable (MTP) device.

An arrow 2208 indicates the direction of the flow of charge carriers during programming operations of the device 2200. An arrow 2210 indicates the direction of the flow of charge carriers during erasing operations of the device 2200.

In the illustrated implementation, the coupling gate (i.e., the negative capacitor combined with the coupling capacitor) is used to enlarge value of the capacitance of the control gate. The associated bit cell is programmed using carrier hot electron ejection (CHE) and an input/output (I/O) type interface. The associated bit cell is erased using metal gate-to-erase gate dielectric corner Fowler-Nordheim (F-N) tunneling. The process for the illustrated implementation adds the erase gate contact (CT EG) mask/oxide etch and spacer removal before CT contact patterning.

Table 2 below illustrates the operation of the NMOS devices described herein according to one or more implementations. Vp1 and Vp2 represent the program voltages. Ve represents the erase voltage. V_{REF} represents the reference voltage for the bit cell sensed voltage comparison.

TABLE 2
NMOS MTP Operation

| Terminate | Operation | Read | Program | Erase |
|---|---|---|---|---|
| Word Line | Selected | V_{CC} | V_{CC} | V_{CC} |
| | Unselected | 0 V | 0 V | V_{CC} |
| Source Line | Selected | 0 V | Vp1 (1~3 V) | 0 V |
| | Unselected | 0 V | 0 V | 0 V |
| Coupling Gate | Selected | V_{CC} | Vp2 (~−5 V) | ~−5 V |
| | Unselected | 0 V | 0 V | 0 V |
| Erase Gate | Selected | 0 V | Vp1 (1~3 V) | Ve (~6 V) |
| | Unselected | 0 V | 0 V | 0 V |
| Bit Line | Selected | V_{REF} | <1 V | 0 V |
| | Unselected | V_{REF} | V_{CC} | 0 V |

Example Process Flow for MTP Devices with P+Contacts in N-Well

FIGS. 23A through 23D illustrate a process integration flow for a method of making a Multiple Time Programmable (MTP) device according to an example implementation of the technology described herein.

FIG. 23A shows a device 2300 divided into a right cell 2302 and a left cell 2304 along a dotted line 2306. Shallow trench isolation (STI) is performed and a p-well 2308 is formed on the left cell 2302 and the right cell 2304. An n-well 2310 is formed on the p-well 2308. A gate dielectric material 2312 (for the gate oxide) is formed on the n-well 2310, e.g., by growth or deposition. The gate dielectric material 2312 may be any suitable oxide or a high-k gate material. Polysilicon material 2314 is deposited on the gate dielectric material 2312 and patterned to make word lines and floating gates.

FIG. 23B shows that source or drain regions 2316 may be implanted in the n-well 2310 to form the P+ source and drain contacts, for example. This may be accomplished using a lightly doped drain (LDD)/halo structure for the channel extension region dopant tuning. The source and drain regions 2316 may be annealed and a self-aligned silicide (salicide) (not shown) may be formed in the source/drain area. Portions of the polysilicon material 2314 may be selectively removed and an oxide material 2318 may be deposited in the remaining area on the gate dielectric material 2312.

In an alternative implementation, the source and drain regions 2316 for the P+ source line may be a deep source region.

FIG. 23B also shows that a metal gate film 2320 may be deposited into the trench after the polysilicon material 2314 is removed, and sidewalls 2322 may be formed on the metal gate film 2320. The metal gate film 2320 may be planarized using chemical-mechanical planarization (CMP) or other suitable mechanism.

Contact trenches may be patterned in an oxide material 2318 and filled with a contact metal 2321. The contact metal may be tungsten (W), copper (Cu), aluminum (Al), or other suitable material. The contact metal 2321 in the trenches 2324 may be planarized using chemical-mechanical planarization (CMP) or other suitable mechanism.

A dielectric film 2326 for a coupling capacitor is deposited on the metal gate film 2320 and the oxide material 2318. The dielectric film 2326 may be SiC, SiN, SiO₂/SiN, SiO₂/SiC, SiO₂/Al₂O₃, SiO₂/SiN/SiO₂, SiO₂/HfOx/SiO₂, SiO₂/Al₂O₃/SiO₂, or the like.

A ferroelectric film 2328 is deposited on the dielectric film 2326. The ferroelectric film 2328 may be doped HfO2, BaTiO₃, PbTiO₃, or other suitable ferroelectric film.

A high resistance metal film 2330 may be deposited on the ferroelectric film 2328. The high resistance metal film 2328 may be TaN, TiN, or other suitable film.

FIG. 23C shows that the high resistance metal film 2330 and the ferroelectric film 2328 have been patterned as a control gate 2332 and a negative capacitor 2334, respectively. An inter-layer dielectric material 2336 has been deposited on the film 2326. The inter-layer dielectric material 2336 may be any suitable oxide material.

Trenches are patterned in the inter-layer dielectric material 2336 and patterned for a combined level 0 metal layer (M0) and erase gate (M0) 2339. Layer 0 metal layer film material 2338 is deposited in the trenches. The level 0 metal layer (M0) material 2338 may be tungsten (W), copper (Cu), aluminum (Al), or other suitable material. The level 0 metal layer (M0) material 2338 may be planarized using chemical-mechanical planarization (CMP) or other suitable mechanism.

FIG. 23D shows that another inter-layer dielectric film 2340 is deposited on the level 0 metal layer (M0) material 2338. The trenches in the inter-layer dielectric material 2340 are Damascene-processed for the voltage plane (V0) and the level 1 metal layer (M1). Metal is deposited in the trenches to form the via0 (V0) 2342 and the level 0 metal layer (M0) 2344. The level 1 metal layer (M1) material 2344 may be tungsten (W), copper (Cu), aluminum (Al), or other suitable material. The level 1 metal layer (M1) material 2344 may be planarized using chemical-mechanical planarization (CMP) or other suitable mechanism. Other logic/circuitry may be formed on the level 1 metal layer (M1) material 2344 and the inter-layer dielectric film 2340 in back-end-of-line (BEOL) processing.

FIG. 24 illustrates a process integration flow for a method of making a Multiple Time Programmable (MTP) device according to an alternative example implementation of the technology described herein. In the illustrated example, a high resistance metal film and a ferroelectric film have been patterned as a control gate 2432 and as a negative capacitor 2434, respectively. An inter-layer dielectric material 2436 has been deposited on the film 2426. The inter-layer dielectric material 2436 may be any suitable oxide material.

A level 0 metal layer (M0) erase mask is added and patterned to open an erase gate trench. An oxide film 2442 is deposited in the erase gate trench. The thickness of the oxide film 2442 may be adjusted to control erase gate efficiency. A metal trench is patterned for a layer 0 metal layer and layer (M0) and a metal layer film material may be deposited in the patterned trench to form a combined an erase gate and a portion of the layer 0 metal layer (M0) 2440. The level 0 metal layer (M0) material may be tungsten (W), copper (Cu), aluminum (Al), or other suitable material. The level 0 metal layer (M0) material may be planarized using chemical-mechanical planarization (CMP) or other suitable mechanism.

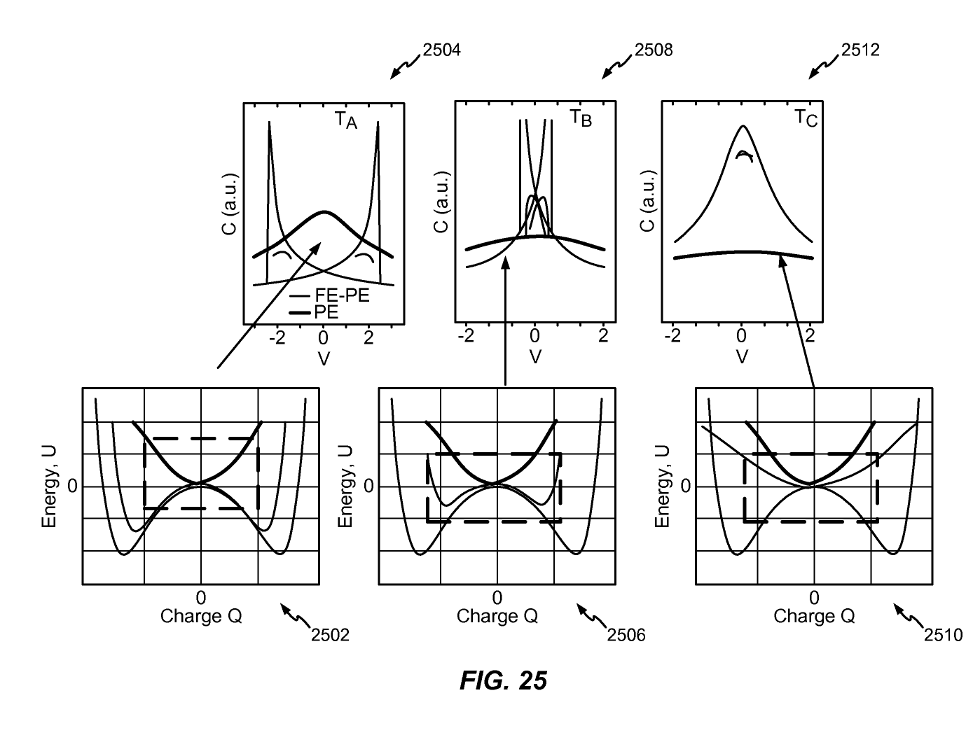

FIG. 25 illustrates graphical representations of modeling of a negative capacitor for a Multiple Time Programmable (MTP) device according to an example implementation of the technology described herein. In the illustrated implementation, a graphical representation 2502 is associated with a graphical representation 2504, a graphical representation 2506 is associated with a graphical representation 2508, and a graphical representation 2510 is associated with a graphical representation 2512. The illustrated graphical representations 2502, 2506, and 2510 are energy versus charge graphical representations for various ferroelectric materials. The illustrated graphical representations 2502, 2506, and 2510 are capacitance versus voltage graphical representations for various ferroelectric materials.

As can be seen in the illustration, as the types of ferroelectric materials move from that which is modeled in the graphical representation 2504 to that which is modeled in the graphical representation 2508 and to that modeled in the graphical representation 2512, the ferroelectric energy becomes smaller. As the types of ferroelectric materials move from that modeled in the graphical representation 2504 to that modeled in the graphical representation 2508 and to that modeled in the graphical representation 2512, the total capacitance becomes larger.

Aspects of the technology described herein and related drawings are directed to specific implementations of the technology. Alternative implementations may be devised without departing from the scope of the technology described herein. Additionally, well-known elements of the technology will not be described in detail or will be omitted so as not to obscure the relevant details.

Although steps and decisions of various methods may have been described serially in this disclosure, some of these steps and decisions may be performed by separate elements in conjunction or in parallel, asynchronously or synchronously, in a pipelined manner, or otherwise. There is no particular requirement that the steps and decisions be performed in the same order in which this description lists them, except where explicitly so indicated, otherwise made clear from the context, or inherently required. It should be noted, however, that in selected variants the steps and decisions are performed in the order described above. Furthermore, not every illustrated step and decision may be required in every implementation/variant in accordance with the technology described herein, while some steps and decisions that have not been specifically illustrated may be desirable or necessary in some implementation/variants in accordance with the technology described herein.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the implementations disclosed herein may be implemented as electronic hardware, computer software, or combinations of both. To show clearly this interchangeability of hardware and software, various illustrative components, blocks, modules, circuits, and steps have been described above generally in terms of their functionality. Whether such functionality is implemented as hardware, software, or combination of hardware and software depends upon the particular application and design constraints imposed on the overall system. Skilled artisans may implement the described functionality in varying ways for each particular application, but such implementation decisions should not be interpreted as causing a departure from the scope of the present technology described herein.

The various illustrative logical blocks, modules, and circuits described in connection with the implementation disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the aspects disclosed herein may be implemented directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an access terminal. Alternatively, the processor and the storage medium may reside as discrete components in an access terminal.

The previous description of the disclosed implementations is provided to enable any person skilled in the art to make or use the technology described herein. Various modifications to these implementations will be readily apparent to those skilled in the art, and the generic principles defined herein may be applied to other implementations without departing from the spirit or scope of the technology described herein. Thus, aspects of the technology described herein are not intended to be limited to the implementations shown herein, but is to be accorded the widest scope consistent with the principles and novel features disclosed herein.

What is claimed is:

1. A multiple time programmable memory, comprising:
a negative capacitor; and
a first transistor having a floating gate, wherein the floating gate is coupled in series with the negative capacitor.

2. The multiple time programmable memory of claim 1, wherein the negative capacitor includes a ferroelectric capacitor and an inter-plate dielectric capacitor.

3. The multiple time programmable memory of claim 1, wherein the first transistor is at least one of an NMOS transistor and a PMOS transistor.

4. The multiple time programmable memory of claim 1, further comprising a control gate coupled in series with the negative capacitor.

5. The multiple time programmable memory of claim 1, further comprising a second transistor,
wherein the first transistor further includes a drain and a source,
wherein the second transistor further includes a drain and a source, and
wherein the source of the first transistor is coupled to the drain of the second transistor.

6. The multiple time programmable memory of claim 1, wherein the drain of the first transistor is coupled to a source line of the multiple time programmable memory and wherein the source of the second transistor is coupled to a bit line of the multiple time programmable memory.

7. The multiple time programmable memory of claim 1, wherein the second transistor includes a gate that is coupled to a word line of the multiple time programmable memory.

8. The multiple time programmable memory of claim 1, further comprising a third transistor, wherein the third transistor includes a gate that is coupled in parallel with the gate of the first transistor and in parallel with the negative capacitor.

9. A method for making a multiple time programmable memory, comprising:
forming a negative capacitor on a substrate;
forming a first transistor on the substrate, wherein the first transistor includes a floating gate; and
coupling the floating gate in series with the negative capacitor.

10. The method for making the multiple time programmable memory of claim 9, wherein the negative capacitor includes ferroelectric material and an inter-plate dielectric material.

11. The method of making the multiple time programmable memory of claim 10, wherein forming the negative capacitor on the substrate comprises:
forming a gate oxide material on the substrate;
forming the floating gate material on the gate oxide material;
forming the inter-plate dielectric material on the floating gate material; and
forming the ferroelectric material on the inter-plate dielectric material.

12. The method of making the multiple time programmable memory of claim 11, further comprising:
forming a high-resistance metal film on the ferroelectric material;
patterning the high-resistance metal film; and
patterning the ferroelectric material.

13. The method of making the multiple time programmable memory of claim 12, further comprising:
forming a first interlayer dielectric material on the high-resistance metal film;
patterning at least one first trench in the first interlayer dielectric material; and
forming a first metal material in the at least one first trench.

14. The method of making the multiple time programmable memory of claim 13, further comprising:
forming a second interlayer dielectric material on the first interlayer dielectric material;
patterning a at least one second trench in the first interlayer dielectric material; and
forming a second metal material in the at least one second trench.

15. A method for making a multiple time programmable memory, comprising:
step for forming a negative capacitor on a substrate;
step for forming a first transistor on the substrate, wherein the first transistor includes a floating gate; and
step for coupling the floating gate in series with the negative capacitor.

16. The method of claim 15, wherein the negative capacitor includes ferroelectric material and an inter-plate dielectric material.

17. The method of claim 15, wherein the negative capacitor includes ferroelectric material and an inter-plate dielectric material.

16. The method of claim 15, further comprising:
step for forming a gate oxide material on the substrate;
step for forming the floating gate material on the gate oxide material;
step for forming the inter-plate dielectric material on the floating gate material; and
step for forming the ferroelectric material on the inter-plate dielectric material.

17. The method of claim 16, further comprising:
step for forming a high-resistance metal film on the ferroelectric material;
step for patterning the high-resistance metal film; and
step for patterning the ferroelectric material.

18. The method of claim 17, further comprising:
step for forming a first interlayer dielectric material on the high-resistance metal film;
step for patterning at least one first trench in the first interlayer dielectric material; and
step for forming a first metal material in the at least one first trench.

19. The method of claim 18, further comprising:
step for forming a second interlayer dielectric material on the first interlayer dielectric material;
step for patterning a at least one second trench in the first interlayer dielectric material; and
step for forming a second metal material in the at least one second trench.

20. A multiple time programmable memory, comprising:
a negative capacitance means; and
a first transistor having a floating gate, wherein the floating gate is coupled in series with the negative capacitance means.

21. The multiple time programmable memory of claim 20, wherein the negative capacitor means includes a ferroelectric capacitor means and an inter-plate dielectric capacitance means.

22. The multiple time programmable memory of claim 20, wherein the first transistor is at least one of an NMOS transistor and a PMOS transistor.

23. The multiple time programmable memory of claim 20, further comprising a control gate coupled in series with the negative capacitance means.

24. The multiple time programmable memory of claim 20, further comprising a second transistor,
wherein the first transistor further includes a drain and a source,
wherein the second transistor further includes a drain and a source, and
wherein the source of the first transistor is coupled to the drain of the second transistor.

25. The multiple time programmable memory of claim 20, wherein the drain of the first transistor is coupled to a source line of the multiple time programmable memory and wherein the source of the second transistor is coupled to a bit line of the multiple time programmable memory.

26. The multiple time programmable memory of claim 20, wherein the second transistor includes a gate that is coupled to a word line of the multiple time programmable memory.

27. The multiple time programmable memory of claim 20, further comprising a third transistor, wherein the third transistor includes a gate that is coupled in parallel with the gate of the first transistor and in parallel with the negative capacitance means.
